(19) United States
(12) Patent Application Publication
(10) Pub. No.: US 2010/0182222 A1
(43) Pub. Date: Jul. 22, 2010

(54) LIGHT-EMITTING DEVICE, DISPLAY APPARATUS AND LIGHTING APPARATUS EACH INCLUDING LIGHT-EMITTING DEVICE AND MANUFACTURING METHOD OF LIGHT-EMITTING DEVICE

(75) Inventors: Kouki ICHIHASHI, Osaka (JP); Takashi OHTA, Kyoto (JP)

Correspondence Address: GREENBLUM & BERNSTEIN, P.L.C., 1950 ROLAND CLARKE PLACE, RESTON, VA, 20191, US

(73) Assignee: Panasonic Corporation, Osaka (JP)

(21) Appl. No.: 12/631,124

(22) Filed: Dec. 4, 2009

(30) Foreign Application Priority Data
Dec. 5, 2008 (JP) 2008-310984

(51) Int. Cl. G09G 3/20; F21V 5/00; H01L 33/00

(52) U.S. Cl. 345/76; 362/311.01; 362/311.06; 438/29; 257/E33.001

(57) ABSTRACT

A light-emitter includes a first electrode layer, a second electrode layer, and a light-emitting layer located between the first and second electrode layers. A gradient index lens is located proximate to the second electrode layer opposite the light-emitting layer and comprises a plurality of concentric parts. The concentric parts are grouped into a central zone and annular zones. Each annular zone includes at least two of the concentric parts. One of the concentric parts included in each annular zone has a refractive index different from a refractive index of another of the concentric parts. A wavelength of light emitted from the light-emitting layer is greater than a radius of the central zone and a width of each annular zone. An effective refractive index of each annular zone decreases in an outward direction from a center of the gradient index lens.

This application is based on application No. 2008-310984 filed in Japan, the contents of which are hereby incorporated by reference.

### BACKGROUND OF THE INVENTION

(1) Field of the Invention

The present invention relates to a light-emitter, a display apparatus and a lighting apparatus each including the light-emitter, and a method of manufacturing the light-emitter.

(2) Description of the Related Art

In recent years, an electroluminescence (EL) device has been used for a display of a mobile phone, a digital camera or the like in order to make the display thinner, increase brightness of the display, and conserve energy. The EL device has a laminating structure in which a transparent electrode layer, a light-emitting layer and an electrode layer are laminated in the stated order on a transparent substrate, for example. In such a laminating structure, a refractive index of the transparent electrode layer and a refractive index of the transparent substrate are different from one another, and light emitted from the light-emitting layer is totally reflected that reaches an interface between the transparent electrode layer and the transparent substrate by a quite large incident angle with respect to the interface. Also, part of light incident on the transparent substrate is totally reflected that reaches an opposing interface that opposes to the interface between the transparent electrode layer and the transparent substrate by a quite large incident angle with respect to the opposing interface. Therefore, the EL device has a problem that light takeoff efficiency is low.

In order to suppress total such an internal reflection components of light incident on the interfaces, a light-emitter including microlenses between a transparent substrate and a transparent electrode layer has been suggested in a Patent Document 1. In the light-emitter described in the Patent Document 1, an incident angle of light with respect to the transparent substrate is reduced by refracting the light by the microlenses such that a divergence angle of light emitted from a light-emitting layer is suppressed. Thus, the total internal reflection component of light incident on an interface of the transparent substrate is suppressed, and the light takeoff efficiency of the light-emitter can be improved.

### [Patent Document]

### [Patent Document 1]

Japanese Patent Application Publication No. 2007-280699

### SUMMARY OF THE INVENTION

In the light-emitter including the above-mentioned conventional microlenses, a diameter of each of the microlenses is as small as between a few tens of μm orders and a few hundreds of μm orders. Therefore, in order to manufacture the microlenses, heat application reflow processing is used in which transparent resin material for lenses is melted by heat application to form intended curved surfaces of the lenses with use of surface tension of the material. In the heat application reflow processing, a plurality of light-emitters are usually brought into a reflow oven altogether and are heated. However, it is difficult to keep a temperature even at all locations in the oven. Thus, there is a limit to how well a temperature is managed. Therefore, the plurality of light-emitters are heated at different temperatures. This leads to a problem that shapes of curved surfaces of the lenses that are formed by the surface tension become uneven. When the shapes of curved surfaces of the lenses that are formed by the surface tension become uneven in the plurality of light-emitters, an effect of suppressing the divergence angle of light emitted from the light-emitting layer varies in each of the light-emitters. As a result, light takeoff efficiencies of the light-emitters vary.

The present invention, in view of the above-stated problem, has an objective to provide a light-emitter that can suppress a variation in light takeoff efficiency, a display apparatus and a lighting apparatus each including the light-emitter, and a method of manufacturing the light-emitter.

One aspect of the present invention is a light-emitter, comprising: a first electrode layer; a second electrode layer; a light-emitting layer positioned between the first electrode layer and the second electrode layer; and a gradient index lens positioned proximate the second electrode layer opposite the light-emitting layer and including a plurality of concentric parts, wherein the plurality of concentric parts are grouped into a central zone and annular zones, each of the annular zones including at least two of the plurality of concentric parts, one of the at least two of the plurality of concentric parts included in each of the annular zones has a refractive index different from a refractive index of another one of the at least two of the plurality of concentric parts, a wavelength of light emitted from the light-emitting layer is equal to or greater than a radius of the central zone and a width of each of the annular zones, and an effective refractive index of each of the annular zones decreases in an outward direction from a center of the gradient index lens.

Note that the concentric parts include a central concentric part which is a circular part including the center, and annular concentric parts.

Also, at least two concentric parts compose each annular zone. Therefore, all of the annular zones may have the same number of concentric parts, or have the different number of concentric parts.

With the above-described gradient index lens, light transmitting through the gradient index lens can be refracted by a gradient of the effective refractive indexes of the gradient index lens. Therefore, it is possible to suppress the divergence angle of the light emitted from the light-emitting layer included in the light-emitter.

When manufacturing the above-described gradient index lens, lithographic processing can be adopted that can manufacture the light-emitter more precisely compared to the heat application reflow processing. Therefore, variation in shapes of the gradient index lenses each included in a corresponding one of the plurality of light-emitters can be suppressed, and variation in light takeoff efficiency among the plurality of light-emitters can be suppressed.

### BRIEF DESCRIPTION OF THE DRAWINGS

These and the other objects, advantages and features of the invention will become apparent from the following description thereof taken in conjunction with the accompanying drawings which illustrate a specific embodiment of the invention. In the drawings:

FIG. 1 schematically shows a sectional view of a light-emitter pertaining to a first embodiment of the present invention;

FIG. 2A schematically shows a sectional view of a gradient index lens included in the light-emitter shown in FIG. 1, and FIG. 2B schematically shows a plane view of the gradient index lens included in the light-emitter shown in FIG. 1;

FIG. 3 shows a refractive index distribution of the gradient index lens shown in FIG. 2A and FIG. 2B;

FIG. 4 shows a width of a higher refractive index annular concentric part included in each zone included in the gradient index lens shown in FIG. 2A and FIG. 2B;

FIG. 5 schematically shows a sectional view that explains principles of the gradient index lens;

FIG. 6A to FIG. 6D show a manufacturing method pertaining to the first embodiment of the present invention, and show manufacturing processes of the gradient index lens;

FIG. 7 shows a flowchart showing area judgment procedures in a patterning process that are main manufacturing processes of the gradient index lens;

FIG. 8 schematically shows a sectional view of a light-emitter pertaining to a second embodiment of the present invention;

FIG. 9A schematically shows a sectional view of a diffraction lens included in the light-emitter shown in FIG. 8, and FIG. 9B schematically shows a plane view of the diffraction lens included in the light-emitter shown in FIG. 8;

FIG. 10 shows a reflective index of the diffraction lens shown in FIG. 9A and FIG. 9B;

FIG. 11 shows a limited range of each of an effective refractive index n0 and a thickness L of the diffraction lens shown in FIG. 9A and FIG. 9B;

FIG. 12A to FIG. 12E each show a width of a higher refractive index annular concentric part included in each zone included in the diffraction lens shown in FIG. 9A and FIG. 9B;

FIG. 13 schematically shows a sectional view of a light-emitter included in an organic EL display according to a third embodiment of the present invention;

FIG. 14 schematically shows a plane view of the gradient index lens included in the light-emitter shown in FIG. 13;

FIG. 15 is a flowchart showing judgment procedures in the patterning process of a manufacturing method pertaining to the third embodiment of the present invention;

FIG. 16A schematically shows a Y-Z sectional view of a lighting apparatus pertaining to a fourth embodiment of the present invention, and FIG. 16B schematically shows an X-Z sectional view of the lighting apparatus pertaining to the fourth embodiment of the present invention; and

FIG. 17 schematically shows a sectional view of the light-emitter pertaining to a modification.

### DESCRIPTION OF THE PREFERRED EMBODIMENT

The light-emitter which is one aspect of the present invention is a light-emitter, comprising: a first electrode layer; a second electrode layer; a light-emitting layer positioned between the first electrode layer and the second electrode layer; and a gradient index lens positioned proximate the second electrode layer opposite the light-emitting layer and including a plurality of concentric parts, wherein the plurality of concentric parts are grouped into a central zone and annular zones, each of the annular zones including at least two of the plurality of concentric parts, one of the at least two of the plurality of concentric parts included in each of the annular zones has a refractive index different from a refractive index of another one of the at least two of the plurality of concentric parts, a wavelength of light emitted from the light-emitting layer is equal to or greater than a radius of the central zone and a width of each of the annular zones, and an effective refractive index of each of the annular zones decreases in an outward direction from a center of the gradient index lens.

With the above-described gradient index lens, light that transmits through the gradient index lens can be refracted by a gradient of the effective refractive indexes of the gradient index lens. Therefore, it is possible to suppress the divergence angle of light emitted from the light-emitting layer included in the light-emitter.

Furthermore, in the one aspect of the present invention, the effective refractive index of each of the annular zones may be approximately equal to a refractive index n(r), wherein

$$n ( r ) = n 0 - ( \frac{ni}{2 fL} ) {r}^{2} ,$$

where r is a distance from the center to an inner circumference radius of a corresponding one of the annular zones, n0 is an effective refractive index of the central zone, f is a focal distance of the gradient index lens, L is a thickness of the gradient index lens, and ni is a refractive index of a layer that is adjacent to a light incident surface of the gradient index lens.

With the above-described gradient index lens, the effect of suppressing the divergence angle of the light emitted from the light-emitting layer is enhanced by making setting such that the effective refractive index of each zone is approximately equal to a refractive index n(r). This suppresses a total internal reflection component of light emitted from the light-emitting layer, and thus the light takeoff efficiency is enhanced. Here, since there may be a manufacturing error, the effective refractive index of each zone is approximately equal to the refractive index n(r) instead of being equal to the refractive index n(r).

Also, a light-emitter which is another aspect of the present invention is a light-emitter, comprising: a first electrode layer; a second electrode layer; a light-emitting layer positioned between the first electrode layer and the second electrode layer; and a diffraction lens positioned proximate the second electrode layer opposite the light-emitting layer and including a plurality of concentric parts, wherein the plurality of concentric parts are grouped into a central zone and annular zones, each of the annular zones including at least two of the plurality of concentric parts, and one of the at least two of the plurality of concentric parts included in each of the annular zones has a refractive index different from a refractive index of another one of the at least two of the plurality of concentric parts, a wavelength of light emitted from the light-emitting layer is equal to or greater than a radius of the central zone and a width of each of the annular zones, and a width ratio of the at least two of the plurality of concentric parts included in each of the annular zones is set such that saw-tooth changes of effective refractive indices of the annular zones occur spatially from a center.

The above-described diffraction lens has the same effect as the above-described gradient index lens. Also, a shorter focal distance can be achieved compared to the gradient index lens since the diffraction effect of light is used by causing the saw-tooth change of the refractive indexes. Therefore, the light-emitter can be further downsized.

Also, according to the another aspect of the present invention, the effective refractive index of each of the annular zones may be approximately equal to a refractive index n(r), wherein

$$n ( r ) = n 0 - ( \frac{ni}{2 fL} ) {r}^{2} + \frac{m λ}{L} ,$$

where r is a distance from the center to an inner circumference radius of a corresponding one of the annular zones, n0 is an effective refractive index of the central zone, f is a focal distance of the diffraction lens, L is a thickness of the diffraction lens, m is an integer incrementally assigned, in order from the center outwardly, starting with 0, to the central zone and the annular zones based on each saw-tooth change, λ is a wavelength of the light emitted from the light-emitting layer, and ni is a refractive index of a layer that is adjacent to a light-emitting surface of the diffraction lens.

With the above-described diffraction lens, the effect of suppressing the divergence angle of the light emitted from the light-emitting layer is enhanced by making setting such that the effective refractive index of each zone is approximately equal to a refractive index n(r). This suppresses a total internal reflection component of light emitted from the light-emitting layer, and thus the light takeoff efficiency is enhanced.

Also, according to the another aspect of the present invention, the integer m may be obtained via a Floor function, and

$$m = Floor ( ( \frac{ni}{2 f λ} ) {r}^{2} ) .$$

Also, according to the another aspect of the present invention, the central zone may include at least two of the concentric parts, when the one of the at least two of the plurality of concentric parts included in each of the annular zones has a higher refractive index n_{high} that is greater than the refractive index of the another of the at least two of the plurality of concentric parts, a thickness L of the diffraction lens and a width ratio of the at least two of the plurality of concentric parts included in the central zone may be set such that an effective refractive index n0 of the central zone satisfies: 0.85n_{high}≦n0≦0.9n_{high}; the thickness L satisfies: 0.9≦L≦1.5; and a relationship between the effective refractive index n0 and the thickness L satisfies:

$$n 0 \geq \frac{( 0.9 {n}_{high} - 0.85 {n}_{high} )}{( 1.5 - 0.9 )} ( L - 0.9 ) + 0.9 .$$

According to the above-described structure, a ratio between a radius of one of two concentric parts including a center of the concentric parts and a width of the other one of the two concentric parts included in the central zone and a range of the thickness of the diffraction lens are limited. This means that the concentric parts included in each of the zones has a size with which the concentric parts can be formed with use of the photolithographic technique. This facilitates the manufacturing of the diffraction lens.

Also, the effective refractive index of each of the annular zones may be approximately equal to a refractive index n(r), and

$$n ( r ) = n 0 - ( ( \frac{ni}{2 fL} ) {r}^{2} + {a}_{n} {r}^{n} ) + \frac{m λ}{L} ,$$

where r is a distance from the center to an inner circumference radius of a corresponding one of the annular zones, n0 is an effective refractive index of the central zone, f is a focal distance of the diffraction lens, L is a thickness of the diffraction lens, m is an integer incrementally assigned, in order from the center outwardly, to the central zone and the annular zones based on each saw-tooth change, λ is a wavelength of the light emitted from the light-emitting layer, ni is a refractive index of a layer that is adjacent to a light incident surface of the diffraction lens, n is an integer greater than two, and aₙ is an n^{th} coefficient.

In the above-described diffraction lens, the calculation accuracy of the refractive index n(r) can be further enhanced. Thus, the effect of suppressing the divergence angle of the light emitted from the light-emitting layer can be further enhanced by making setting such that the refractive index n(r) having improved calculation accuracy is approximately equal to the effective refractive index of each zone. This suppresses the total internal reflection component of the light emitted from the light-emitting layer, and thus the light takeoff efficiency is further enhanced.

Also, according to the another aspect of the present invention, m may be obtained via a Floor function, and

$$m = Floor ( ( \frac{ni}{2 fL} ) {r}^{2} + {a}_{n} {r}^{n} ) .$$

Also, a number of the at least two of the plurality of concentric parts included in each of the annular zones may be two. Thus, since such a gradient index lens (diffraction lens) has a simpler structure than a gradient index lens (diffraction lens) having three or more concentric parts in each zone, the manufacturing of such a gradient index lens (diffraction lens) can be facilitated.

Also, a transparent layer may be positioned between the gradient index lens and the second electrode layer.

Also, a refractive index of the transparent layer may be equal to a lowest one of refractive indexes of the plurality of concentric parts.

Also, the radius of the central zone may be approximately equal to the width of each of the annular zones.

Also, the width of each of the plurality of concentric parts may be at least 40 nm.

Also, the one of the at least two of the plurality of concentric parts may comprise a transparent material that is one of titanium oxide, zirconium oxide, niobium oxide, silicon nitride silicon oxide, and space, and the another one of the at least two of the plurality of concentric parts may comprise another one of the transparent material.

Also, a display apparatus which is another aspect of the present invention may have a plurality of pixels each including the light-emitter. The same effect as the effect of the light-emitter can be obtained with above-described display apparatus.

Also, in the light emitter included in the display device, a width ratio of the at least two of the plurality of concentric parts included in each of the annular zones may be set according to a type of light emitted from the light-emitting layer, the type of light being at least one of a red light, a green light and a blue light.

Also, a lighting apparatus which is another aspect of the present invention may have the light-emitter. The same effect as the effect of the light-emitter can be obtained with above-described lighting apparatus.

Also, one aspect of the present invention is a method of manufacturing a light-emitter, the method comprising: a first process of forming a resist pattern for forming a gradient index lens including a plurality of concentric parts, each of the plurality of concentric parts having one of a lower refractive index and a higher refractive index, the concentric parts having the lower refractive index and the concentric parts having the higher refractive index being arranged alternately from a center, the plurality of concentric parts being grouped into a central zone and annular zones, the central zone having a radius that is approximately equal to a width of each of the annular zones and including one of one and two of the plurality of concentric parts, each of the annular zones including one of the plurality of concentric parts having the lower refractive index and one of the plurality of concentric parts having the higher refractive index; and a second process of forming the gradient index lens with the resist pattern, the gradient index lens formed proximate a second electrode layer and opposite a light-emitting layer, the light emitting layer positioned between a first electrode and the second electrode, wherein the first process includes: forming a resist film; selecting a selected position (x, y) located on a surface of the resist film; calculating a distance r between the selected position (x, y) and a reference position (x₀, y₀) that corresponds to the center; calculating a number k of one of the central zone and one of the annular zones that includes the selected position (x, y) based on the calculated distance r and the width c of each of the annular zones; calculating a width a of one of the concentric parts having the higher refractive index, wherein

$$a = \frac{c}{( {n}_{high} - {n}_{low} )} ( n 0 - {n}_{low} - ( \frac{ni}{2 fL} ) {( k - 1 )}^{2} {c}^{2} ) ,$$

c is a width of each of the annular zones, n_{low} is the lower refractive index, n_{high} is the higher refractive index, ni is a refractive index of a layer that is adjacent to a light incident surface of the gradient index lens, f is a focal distance of the gradient index lens, L is a thickness of the gradient index lens, and n0 is an effective refractive index of the central zone; and judging whether to remove a portion of the resist film including the selected position (x, y) depending on whether the calculated distance r satisfies: r≦kc−a.

In the above-described method of manufacturing the light-emitter, lithographic processing can be adopted that can manufacture the light-emitter more precisely compared to the heat application reflow processing. Therefore, variation in shapes of the gradient index lenses included each in a corresponding one of the plurality of light-emitters can be suppressed, and variation in light takeoff efficiency among the plurality of light-emitters can be suppressed.

Also, another aspect of the present invention is a method of manufacturing a light-emitter, the method comprising: a first process of forming a resist pattern for forming a diffraction lens including a plurality of concentric parts, each of the plurality of concentric parts having one of a lower refractive index and a higher refractive index, the concentric parts having the lower refractive index and the concentric parts having the higher refractive index being arranged alternately from a center, the plurality of concentric parts being grouped into a central zone and annular zones, the central zone having a radius that is approximately equal to a width of each of the annular zones and including one of one and two of the plurality of concentric parts, each of the annular zones including one of the plurality of concentric parts having the lower refractive index and one of the plurality of concentric parts having the higher refractive index, a width ratio of the plurality of concentric parts included in each of the annular zones being set such that saw-tooth changes of effective refractive indices of the annular zones occur spatially from the center; and a second process of forming the diffraction lens with the resist pattern, the diffraction lens formed proximate a second electrode layer and opposite a light-emitting layer, the light emitting layer positioned between a first electrode and the second electrode, wherein the first process includes: forming a resist film; selecting a selected position (x, y) located on a surface of the resist film; calculating a distance r between the selected position (x, y) and a reference position (x₀, y₀) that corresponds to the center; calculating a number k of one of the central zone and one of the annular zones that includes the selected position (x, y) based on the calculated distance r and the width c of each of the annular zones; calculating a width a of one of the concentric parts having the higher refractive index, wherein

$$a = \frac{c}{( {n}_{high} - {n}_{low} )} ( n 0 - {n}_{low} - ( \frac{ni}{2 fL} ) {( k - 1 )}^{2} {c}^{2} + \frac{m λ}{L} ) ,$$

c is a width of each of the annular zones, n_{low} is the lower refractive index, n_{high} is the higher refractive index, ni is a refractive index of a layer that is adjacent to a light incident surface of the diffraction lens, f is a focal distance of the diffraction lens, L is a thickness of the diffraction lens, n0 is an effective refractive index of the central zone, m is an integer incrementally assigned, in order from the center outwardly, starting with zero, to the central zone and the annular zones based on each saw-tooth change, and λ is a wavelength of the light emitted from the light-emitting layer; and judging whether to remove a portion of the resist film including the selected position (x, y) depending on whether the calculated distance r satisfies: r≦kc−a.

In the above-described method of manufacturing the light-emitter, the lithography, for example, may be adopted that can manufacture the lens more precisely compared to the heat application reflow processing. Therefore, variation in shapes of the diffraction lenses each included in a corresponding one of the plurality of the light-emitters can be suppressed, and thus the variation in light takeoff efficiency among the plurality of light-emitters can be suppressed.

The following describes a light-emitter according to embodiments of the present invention, a display apparatus and a lighting apparatus each including the light-emitter, and a method of manufacturing the light-emitter, with reference to the attached drawings.

### First Embodiment

<Overall Structure of Light-Emitter>

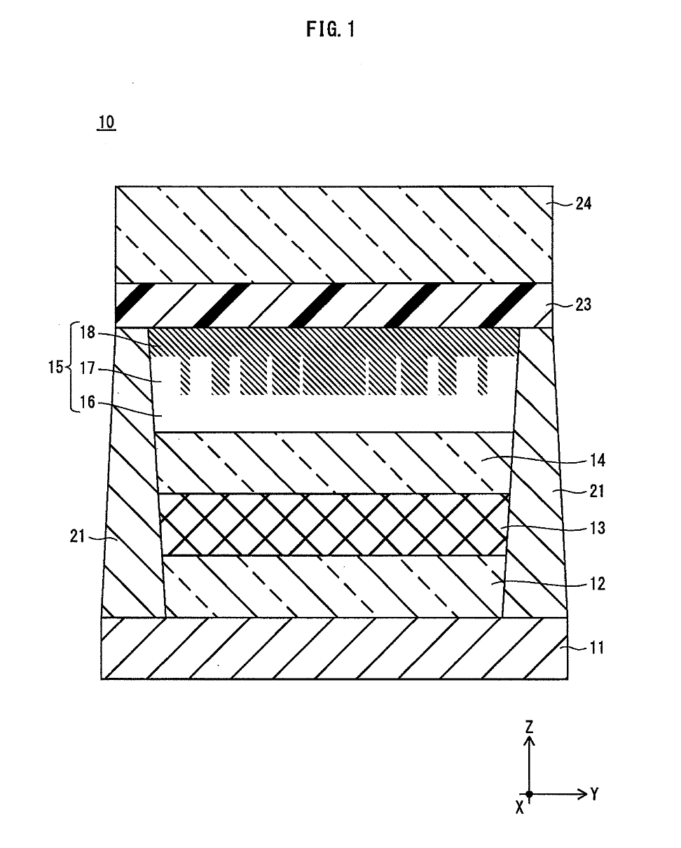

FIG. 1 schematically shows a sectional view showing a top-emission type light-emitter 10 as a light-emitter pertaining to the first embodiment of the present invention. The light-emitter 10 includes a substrate 11, a positive electrode 12 (first electrode layer), a light-emitting layer 13, a negative transparent electrode 14 (second electrode layer) and a lens layer 15 that are laminated in the stated order. Furthermore, the light-emitter 10 includes: a plurality of banks 21 that define forming areas of layers 12 to 15, and are formed on the substrate 11; a sealing layer 23 formed on the lens layer 15 and banks 21; and a glass plate 24.

The light-emitting layer 13 includes a hole transport layer, an organic EL layer and an electron transport layer that are laminated in the stated order on the electrode layer 12.

The sealing layer 23 is formed by bonding and fixing the glass layer 24 and the lens layer 15 so as to keep moisture and oxygen for example, included in an outdoor air from entering the layers 12 to 15 included in the light-emitter.

<Detailed Structure: Lens>

The following describes the lens layer 15.

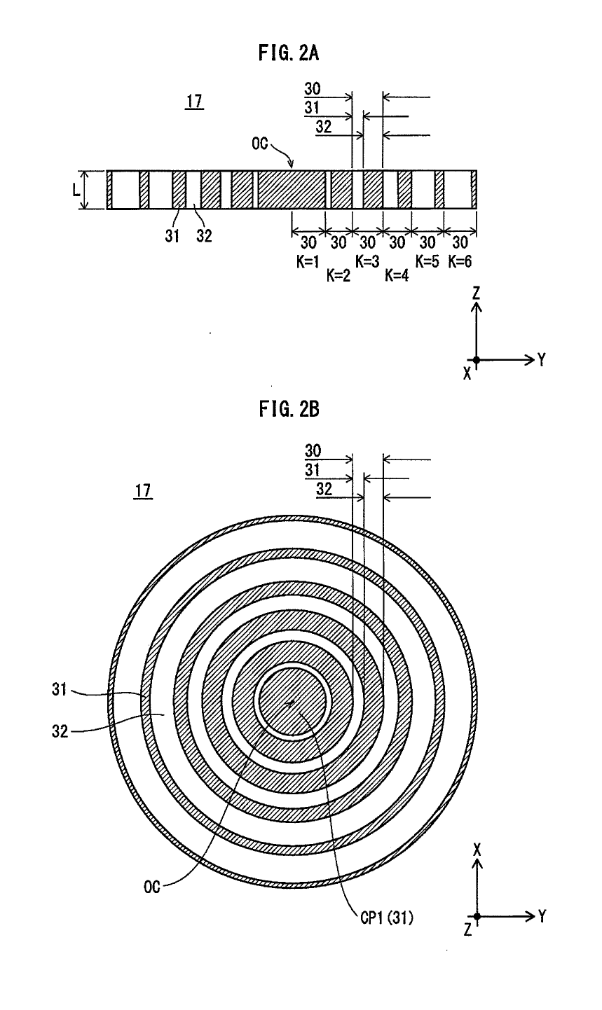

The lens layer 15 is composed of three layers that are a low refractive index layer 16, a gradient index lens 17 and a high refractive index layer 18 that are laminated in the stated order on the transparent electrode 14. These three layers 16 to 18 are each formed of a low refractive index transparent material A or/and a high refractive index transparent material B that have a different refractive index. The low refractive index layer 16 is formed only of the low refractive index transparent material A, and the high refractive index layer 18 is formed only of the high refractive index transparent material B. Meanwhile, the gradient index lens 17 is formed of both the low refractive index transparent material A and the high refractive index transparent material B. FIG. 2A and FIG. 2B show the gradient index lens 17. FIG. 2A schematically shows a sectional view of the gradient index lens 17, and FIG. 2B schematically shows a plane view of the gradient index lens 17. As shown in FIG. 2A and FIG. 2B, the gradient index lens 17 includes a plurality of concentric parts 31 and 32 that are formed in an XY direction. Note that one of the concentric parts 31 including the center OC is referred to as a CP1 and is circular, and the rest of the concentric parts 31 and the concentric parts 32 are annular. The concentric parts 31 are each formed of the high refractive index transparent material B, and the concentric parts 32 are each formed of the low refractive index transparent material A. The low refractive index concentric parts 32 and the high refractive index concentric parts 31 are alternately arranged outwardly from the center OC of the concentric parts. The concentric parts are grouped into areas that are repeatedly-arranged zones 30 in order of closeness to the center. The zones include a central zone and annular zones. Both the central zone and the annular zones are given a reference numeral “30”. In each of the annular zones 30, one of the low refractive index concentric parts 32 and one of the high refractive index concentric parts 31 are arranged in this order. A number assigned to each of the zones 30 that are arranged outwardly from the center OC is expressed as “k”, and the number “k” is an integer that is equal to or larger than one. Note that the CP1 (central concentric part 31) forms the central zone 30 (k=1) according to the present embodiment. Also, a straight line that passes through the center OC and extends in a thickness direction of the gradient index lens 17 corresponds to an optical axis of the gradient index lens 17.

A radius of the central zone 30 and widths c of the annular zones 30 are each equal to or less than a wavelength of light emitted from the light-emitting layer 13, and has the same value of 200 [nm] in the present embodiment.

The low refractive index transparent material A is SiO₂, and the high refractive index transparent material B is TiO₂. A refractive index of SiO₂ is 1.46, and a refractive index of TiO₂ is 2.53.

<Refractive Index Distribution>

The following describes a design concept of the refractive index distribution of the gradient index lens 17.

In general, a refractive index n (r) of a refractive index distribution (GRIN, more accurately, “Radial GRIN”) lens is expressed by the following equation (1) when a distance from the optical axis is r [μm], a refractive index on the optical axis is n0, a focal distance is f [μm], a thickness of the gradient index lens is L [μm], and a refractive index of a layer that is adjacent to a light incident surface of the gradient index lens is ni.

$$n ( r ) = n 0 - ( \frac{ni}{2 fL} ) {r}^{2} \qquad ( 1 )$$

In the gradient index lens 17, setting is made such that an effective refractive index n_{eff} is approximately equal to a refractive index n(r) determined by the above-stated equation (1) when an inner circumference radius of the zone 30 is a distance r, and an effective refractive index of the central zone 30 is n0. In order to obtain this effective refractive index n_{eff}, it is necessary to adjust a ratio between widths (in a radius direction) a and b of the high refractive index concentric part 31 and the low refractive index concentric part 32 respectively that are included in the zone 30.

The following describes how to adjust the ratio between the width a and the width b.

The effective refractive index n_{eff} of each of the zones 30 is obtained by the following equation (2) when the refractive index of the high refractive index concentric part 31 is n_{high}, and the refractive index of the low refractive index concentric part 32 is n_{low}.

$${n}_{eff} = \frac{( a \times {n}_{high} + b \times {n}_{low} )}{( a + b )} \qquad ( 2 )$$

A sum of the width a and the width b is a width c of each annular zone 30. Therefore, the effective refractive index n_{eff} is obtained by the following equation (3) when the width c is used instead of the width b.

$${n}_{eff} = \frac{( a \times {n}_{high} + ( c - a ) \times {n}_{low} )}{c} \qquad ( 3 )$$

In the above-stated equations (2) and (3), the effective refractive index n_{eff} of the zone 30 can be increased if a ratio of the width a to the width c is increased while the refractive index n_{eff} can be decreased if the ratio of the width a to the width c is decreased.

In view of the above, in order to obtain the effective refractive index n_{eff} of each of the zones 30 that is a target refractive index n(r), the width a is obtained by the following equation (4) when the inner circumference radius of the zone 30 is a distance r.

$$a = \frac{c}{( {n}_{high} - {n}_{low} )} ( n 0 - {n}_{low} - ( \frac{ni}{2 fL} ) {r}^{2} ) \qquad ( 4 )$$

The width b is calculated with use of the width a obtained by the above-stated equation (4) and the width c.

<Example of Refractive Index Distribution>

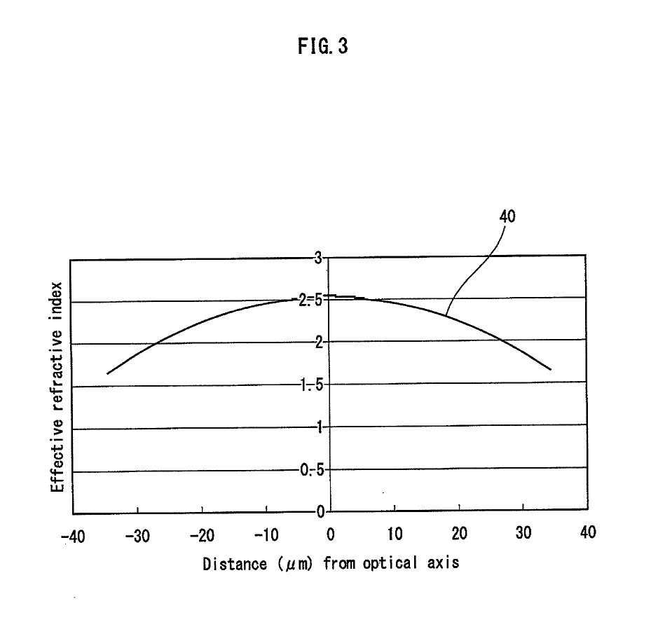

FIG. 3 shows a refractive index distribution of the gradient index lens. In FIG. 3, a vertical axis shows an effective refractive index n_{eff}, and a horizontal axis shows a distance r from the center OC. The distance r in an arbitrary direction from the center OC is expressed by a positive (+) value, while the distance r in an opposite direction from the arbitrary direction is expressed by a negative (−) value.

A refractive index distribution curve 40 as shown in FIG. 3 has an effective refractive index n_{eff} set based on the refractive index obtained by the above-stated equation (1). Note that parameters used as examples here are as follows. A focal distance f of the gradient index lens 17 is 1000 [μm], a thickness L of the gradient index lens 17 is 1 [μm], a wavelength λ of light emitted from the light-emitting layer 13 is 532 [nm], the effective refractive index n0 of the central zone 30 in the wavelength λ is 2.53, and the refractive index ni in the wavelength λ is 1.46. The effective refractive index n0 is used as the refractive index (TiO₂=2.53) of the CP1 which is the central zone 30. The refractive index ni is used as the refractive index (SiO₂=1.46) of the low refractive index layer 16. Note that the gradient index lens 17 has an effective diameter of 70 [μm], and the number of zones 30 included in the gradient index lens 17 is 350.

The refractive index distribution curve 40 shows that the effective refractive index is highest at the center OC, and that the effective refractive index slightly decreases as the distance r increases.

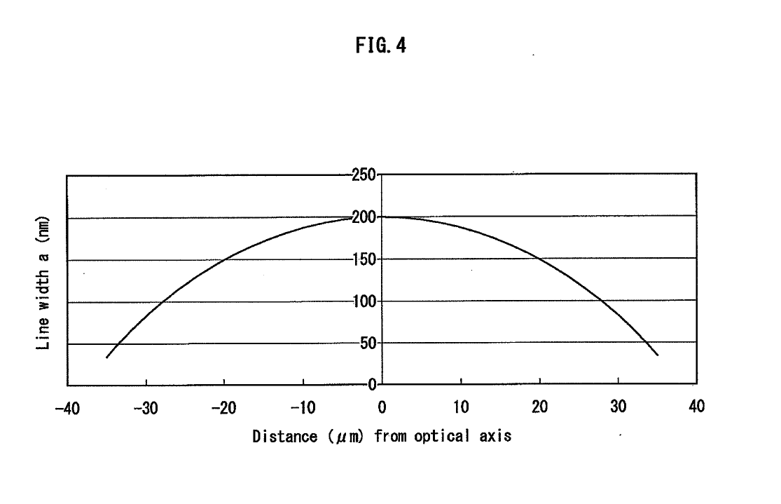

FIG. 4 plots the widths a in zones 30 for realizing the refractive index distribution shown in FIG. 3. In FIG. 4, a vertical axis shows a width a of each of the high refractive index concentric parts 31, and a horizontal axis shows the distance r from the center OC.

The central zone 30 has the maximum width a of 200 [nm]. A zone 30 more distant from the center OC has a smaller width a. According to this example, the minimum width a is 32.8 [nm] with which the gradient index lens can be manufactured in a photolithographic method.

<Description on Principles of Lens>

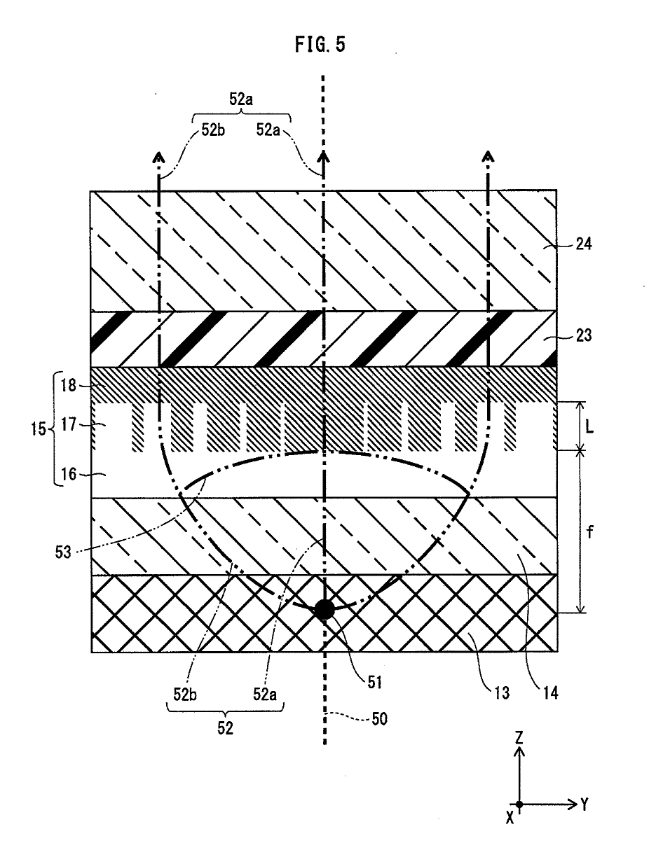

FIG. 5 schematically shows a sectional view of the gradient index lens 17 for describing principles thereof.

In FIG. 5, the optical axis of the gradient index lens 17 is given a reference numeral of 50, and a point light source of the light-emitting layer 13 located in a focal distance f on the optical axis 50 is given a reference numeral of 51. Also, a light beam of light emitted from the point light source 51 is given a reference numeral of 52, and an incident wavefront of light that is emitted from the point light source 51 to the gradient index lens 17 is given a reference numeral of 53. The light beam 52 is divided into a light beam 52a that passes on the optical axis 50, and a light beam 52b that passes through a position distant from the optical axis 50.

In the present embodiment, since the width c of each zone 30 included in the gradient index lens 17 is shorter than a wavelength of the light emitted from the light-emitting layer 13, the light passes through the gradient index lens 17 in the same manner as it passes though a refractive index (GRIN, more accurately, “Radial GRIN”) distribution lens in which the refractive index continuously changes. Therefore, in the gradient index lens 17, light that passes through a position more distant from the optical axis 50 is refracted to a side closer to the optical axis 50 due to a refractive effect, like the light beam 52b shown in FIG. 5.

In the above-described light-emitter 10, the divergence angle of the light emitted from the light-emitting layer 13 is suppressed by the gradient index lens 17, and the total internal reflection component of light incident on each of an interface between the gradient index lens 17 and the high refractive index layer 18, an interface between the high refractive index layer 18 and the sealing layer 23, and an interface between the sealing layer 23 and the glass plate 24 are suppressed. Thus, the light takeoff efficiency of the light-emitter 10 can be improved.

Note that although silicon oxide series SiO₂ is used as the low refractive index transparent material A, and titanium oxide series TiO₂ is used as the high refractive index transparent material B in the present embodiment, examples of materials that can be used as the low or high refractive index transparent materials are as follows: zirconium oxide series such as ZrO₂; niobium oxide series such as Nb₂O₅; and silicon nitride series such as Si₃N₄ or Si₂N₃.

<Detailed Structure Substrate, Electrode and Light-Emitting Layer>

The following describes materials used for the substrate 11, the electrode 12, the light-emitting layer 13 and the transparent electrode 14 that compose the light-emitter 10.

<<Substrate>>

Examples of materials that can be used for the substrate 11 are: a glass plate such as soda glass, nonluminescent glass, phosphate glass and boric-acid glass; a quart plate; a plastic plate or a plastic film such as acrylic resin, styrene resin, polycarbonate resin, epoxy resin, polyethylene, polyester and silicon resin; and a metal plate or a metal foil such as alumina.

Note that it is required that the substrate 11 is a transparent substrate such as a glass plate in the case where the light-emitter 10 is a bottom-emission type light-emitter that allows light to enter from the substrate 11.

<<Electrode>>

A singe alkali metal such as sodium or lithium or alkali alloy thereof may be used for the electrode 12. Also, alkaline-earth metal such as calcium or magnesium or alkaline-earth alloy thereof may be used for the electrode 12. The alloy may include aluminum, silver or indium. Also, a part of third group metals such as gallium or indium may be included in the alloy.

The transparent electrode 14 is composed of a conductive material having enough translucency to transmit the light emitted from the light-emitting layer 13. Preferably, indium tin oxide (ITO) or indium zinc oxide (IZO), for example, is used for the transparent electrode 14. This is because a preferable conductivity can be obtained even if film formation is performed at a room temperature.

<<Light-Emitting Layer>>

The light-emitting layer 13 may be single-layered or multi-layered. Also, the light-emitting layer 13 may include an organic EL layer including an organic light emitter. Furthermore, the light-emitting layer 13 may include the electron transport layer and the hole transport layer that sandwich the organic EL layer therebetween. Furthermore, the light-emitting layer may include an electron-injection layer and/or a hole-injection layer. The electron-injection layer and the hole-injection layer can be formed in an evaporation method, a spin coat method or a cast method, for example.

Organic EL Layer

To give a concrete example, fluorescent materials disclosed in Japanese Patent Application Publication No. H5-163488 that can be used for the organic EL layer are: oxinoid compounds, perylene compounds, coumalin compounds, azacoumalin compounds, oxazole compounds, oxadiazole compounds, perinone compounds, pyrrolopyrrole compounds, naphthalene compounds, anthracene compounds, fluorene compounds, fluoranthene compounds, tetracene compounds, pyrene compounds, coronene compounds, quinolone compounds, azaquinolone compounds, pyrazoline derivatives, pyrazolone derivatives, rhodamine compounds, chrysene compounds, phenanthrene compounds, cyclopentadiene compounds, stilbene compounds, diphenylquinone compounds, styryl compounds, butadiene compounds, dicyanomethylenepyran compounds, dicyanomethylenethiopyran compounds, fluorescein compounds, pyrylium compounds, thiapyrylium compounds, selenapyrylium compounds, telluropyrylium compounds, aromatic aldadiene compounds, oligophenylene compounds, thioxanthene compounds, anthracene compounds, cyanine compounds, acridine compounds, metal complexes containing 8-hydroxyquinoline derivatives, metal complexes containing 2,2′-bipyridine derivatives, group III metal complexes containing Schiff base, metal complexes containing oxine, rare earth metal complexes, etc. The organic EL layer may be formed in the evaporation method, the spin coat method or the cast method for example.

Electron Transport Layer

To give a concrete example, chemical compounds disclosed in Japanese Patent Application Publication No. H5-163488 that can be used for the electron transport layer having the electron transport ability are: nitro-substituted fluorenone derivatives, thiopyran dioxide derivatives, diphenylquinone derivatives, perylene tetracarboxyl derivatives, anthraquinodimethane derivatives, fluorenylidenemethane derivatives, anthrone derivatives, oxadiazole derivatives, perynone derivatives, derivatives of quinoline complexes, etc.

Hole Transport Layer

To give a concrete example, materials disclosed in Japanese Patent Application Publication No. H5-163488 that can be used for the hole transport layer are: triazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, oxazole derivatives, styrylanthracene derivatives, fluorenone derivatives, hydrazone derivatives, stilbene derivatives, porphyrin compounds, aromatic tertiary amine compounds, styryl amine compounds, butadiene compounds, polythiophene derivatives, hydrazone derivatives, triphenylmethane derivatives and tetraphenylbenzine derivative. However, particularly preferable materials are porphyrin compounds, aromatic tertiary amine compounds and styrylamine compound.

<Manufacturing Method>

The following specifically describes a method of manufacturing the gradient index lens 17.

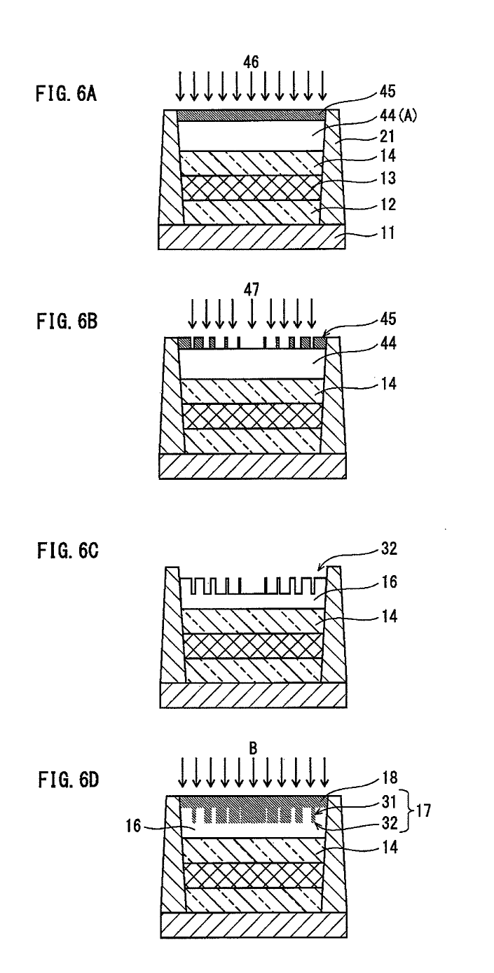

The gradient index lens 17 having the above-described structure can be manufactured using the photolithographic technique. FIG. 6A to FIG. 6D show a method of manufacturing the gradient index lens 17.

<<Photoresist Application and Patterning>>

Firstly, a low refractive index film 44 composed of a low refractive index transparent material A (SiO₂) is formed on the transparent electrode 14 with use of a sputtering apparatus, as shown in FIG. 6A. A resist film 45 is formed by applying resist on the low refractive index film 44. A thickness of each of the low refractive index film 44 and the resist film 45 is 1 [μm].

Then, a concentric patterning 46 is performed on the resist film 45 with use of an electron-beam lithography apparatus. In this patterning 46, the electron-beam lithography apparatus judges whether each selected position located on an upper surface of the resist film 45 belongs to an area forming the low refractive index concentric part 32 or an area forming the high refractive index concentric part 31. When the electron-beam lithography apparatus judges that the selected position belongs to the area forming the high refractive index concentric part 31, the electron-beam lithography apparatus performs electron-beam irradiation.

<<Procedures for Area Judgment>>

The following describes procedures for the area judgment by the electron-beam lithography apparatus.

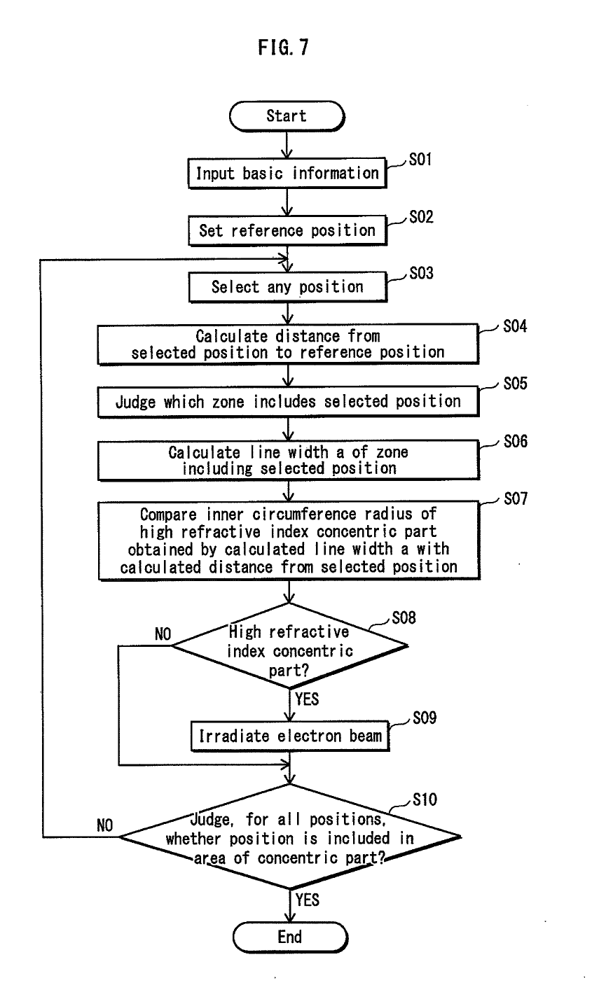

FIG. 7 is a flow chart showing the procedures for the area judgment in the patterning process.

[1] Firstly, after-mentioned design basic information on a lens to be manufactured is input in the electron-beam lithography apparatus (S01).

{Basic Information}

The basic information includes a focal distance f [μm], a thickness L of the gradient index lens [μm], a refractive index ni of a layer that is adjacent to a light incident surface of the gradient index lens 17, a refractive index n_{high} of each of the high refractive index concentric parts 31, a refractive index n_{low} of each of the low refractive index concentric parts 32, an effective refractive index n0 of the central zone 30 and a size of the gradient index lens, for example.

[2] A position of an optical axis on the upper surface of the resist film 45 is set as a reference position (x₀, y₀) (S02).

[3] Any position on the upper surface of the resist film 45 on which the area judgment has not been performed is selected, and defined as a selected position (x, y) (S03).

[4] A distance r between the selected position (x, y) and the reference position (x₀, y₀) is calculated by the following equation (5) (S04).

r=\sqrt{(x−x₀)²+(y−y₀)²} (5)

[5] The number k of the zone 30 including the position (x, y) is obtained by the following equation (6) with use of the calculated distance r and the width c of the zone 30 (S05).

(k−1)c≦r≦kc (6)

(k−1)c in the above-stated equation (6) is an inner circumference radius of the k^{th} zone 30, and kc is an outer circumference radius thereof.

[6] The width a of the high refractive index concentric part 31 in the zone 30 is obtained by the following equation (7) with use of the calculated distance r and the number k of the zone 30 (S06).

$$a = \frac{c}{( {n}_{high} - {n}_{low} )} ( n 0 - {n}_{low} - ( \frac{ni}{2 fL} ) {( k - 1 )}^{2} {c}^{2} ) \qquad ( 7 )$$

Note that the above-state equation (7) is an equation in which the distance r in the above-stated equation (4) is replaced with an inner circumference radius (k−1)c of the k^{th} zone 30.

[7] An inner circumference radius of the high refractive index concentric part 31 obtained by the calculated width a is compared, in the following equation (8), with the distance r calculated in Step S04 (S07).

r≦kc−a (8)

When the above-stated equation (8) is satisfied, the electron-beam lithography apparatus judges that the selected position (x, y) belongs to the area forming the low refractive index concentric part 32. When the above-stated equation (8) is not satisfied, on the other hand, the electron-beam lithography apparatus judges that the selected position (x, y) belongs to the area forming the high refractive index concentric part 31 (S08).

[8] In Step S08, when the electron-beam lithography apparatus judges that the selected position (x, y) belongs to the area forming the low refractive index concentric part 32, the electron-beam lithography apparatus proceeds to step S10 without performing the electron-beam irradiation. When the electron-beam lithography apparatus judges that selected position (x, y) belongs to the area forming the high refractive index concentric part 31, the electron-beam lithography apparatus performs the electron-beam irradiation on the selected position (x, y) (S09).

[9] It is checked whether or not the area judgment is performed on all of the positions on the upper surface of the resist film 45 (S10). If the area judgment is not performed on any of the positions, a series of steps S03 to S09 is repeated.

An exhaustive patterning in which the concentric part is formed into around 30 [nm] in width can be performed by using such an electron beam.

<<Development, Etching and Resist Removal>>

As shown in FIG. 6B, a fine pattern for gradient index lens 17 is formed by developing the resist film 45 on which the electron-beam irradiation is performed in the above-stated judgment procedures, and performing etching 47 on the low refractive index film 44. This fine pattern corresponds to a low refractive index concentric parts 32 included in the gradient index lens 17. In the present embodiment, since the low refractive index layer 16 is provided between the transparent electrode 14 and the gradient index lens 17, setting is made such that a through-hole is not formed on the low refractive index film 44 by the etching 47. Note that when a layer such as the low refractive index layer 16 is not provided between the transparent electrode 14 and the gradient index lens 17, setting is made such that the gradient index lens 17 is formed on the transparent electrode 14 by forming through-holes on the low refractive index film 44 by the etching 47.

Next, the resist film 45 is removed. FIG. 6C shows a state in which the plurality of low refractive index concentric part 32 and the low refractive index layer 16 are exposed.

<<Plasma CVD and Post Bake>>

Subsequently, as shown in FIG. 6D, the high refractive index transparent material B (TiO₂) is deposited in space that exists among the plurality of low refractive index concentric parts 32 with use of the plasma CVD. At this time, the high refractive index transparent material B (TiO₂) is also deposited on each of the low refractive index concentric parts 32. Thus, the plurality of high refractive index concentric parts 31 and the high refractive index layer 18 can be formed.

Then, a surface of the high refractive index layer 18 is polished. Finally, the gradient index lens 17, the low refractive index layer 16 and the high refractive index layer 18 are formed by performing a post bake on the gradient index lens 17, the low refractive index layer 16 and the high refractive index layer 18.

According to the above-described method of manufacturing the gradient index lens 17, it is possible to evenly and precisely manufacture the concentric parts 31 and 32 of the gradient index lens 17 that are up to 30 [nm] in width, using the photolithographic technique. Thus, an adjustment of each of the widths a and b of the concentric parts 31 and 32 included in each zone 30 can be performed minutely. Therefore, the effective refractive index n_{eff} can be accurately matched with the refractive index n(r) determined by the above-stated equation (1) with the inner circumference radius of the zone 30 being the distance r. Thus, an effect can be enhanced that the divergence angle of the light emitted from the light-emitting layer 13 is suppressed by the gradient index lens 17. As a result, it is possible to suppress the total internal reflection component of light incident on each of an interface between the gradient index lens 17 and the high refractive index layer 18, an interface between the high refractive index layer 18 and the sealing layer 23 and, an interface between the sealing layer 23 and the glass plate 24 that are included in the light-emitter 10, and the light takeoff efficiency can be improved.

### Second Embodiment

<Overall Structure of Light-Emitter>

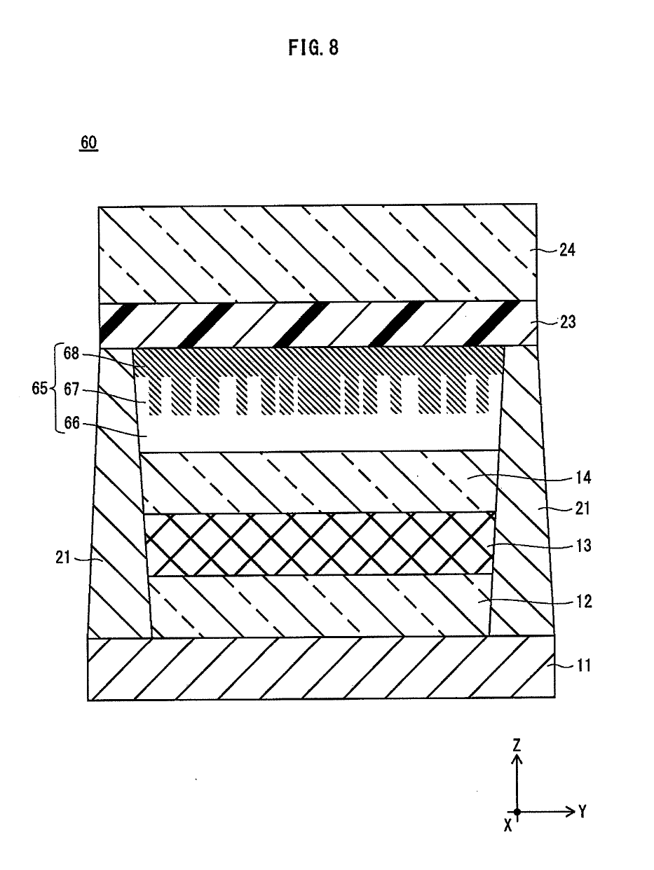

FIG. 8 schematically shows a sectional view of a light-emitter 60 pertaining to a second embodiment of the present invention.

The light-emitter 60 is different from the light-emitter 10 pertaining to the above-described first embodiment in that the light-emitter 60 has a diffraction lens instead of the gradient index lens 17. Note that elements same as the elements of the light-emitter 10 shown in FIG. 1 are given the same reference numerals, and the descriptions thereof are omitted for the purpose of simplification.

A lens layer 65 included in the light-emitter 60 is composed of three layers that are a low refractive index layer 66, a diffraction lens 67 and a high refractive index layer 68 that are laminated in this order on the transparent electrode 14.

<Detailed Structure: Lens>

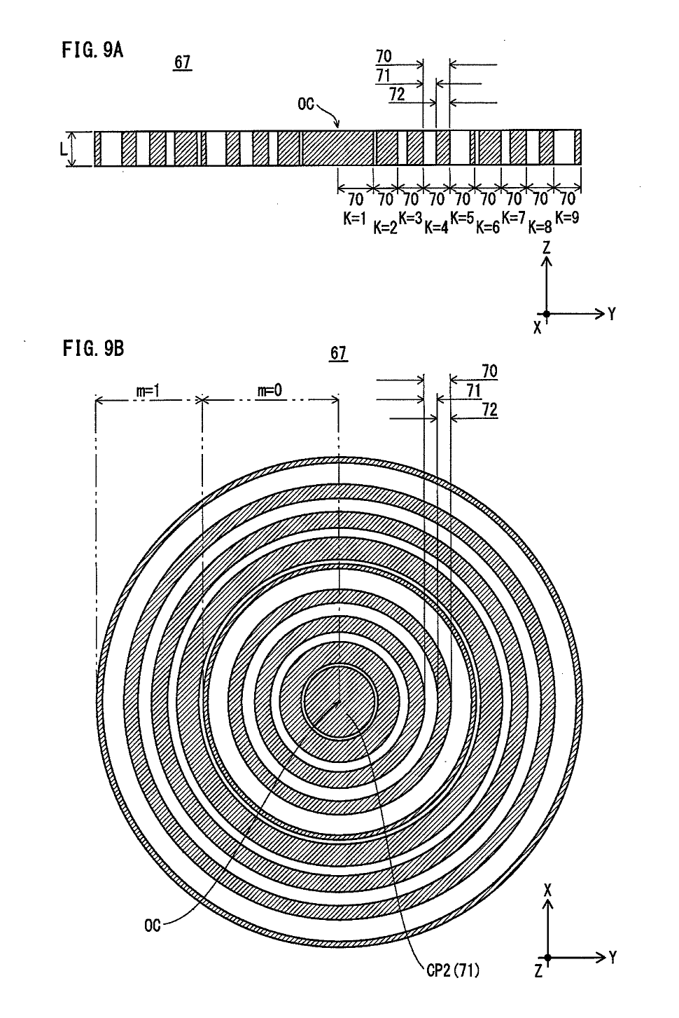

FIG. 9A and FIG. 9B show the diffraction lens 67. FIG. 9A schematically shows a sectional view of the diffraction lens 67, and FIG. 67B schematically shows a plane view of the diffraction lens 67.

As shown in FIG. 9A and FIG. 9B, the diffraction lens 67 includes low refractive index concentric parts 72 and high refractive index concentric parts 71 that are alternately arranged in an XY direction. Note that one of the concentric parts 71 including the center OC is referred to as a CP2 and is circular, and the rest of the concentric parts 71 and the concentric parts 72 are annular. The concentric parts included in the diffraction lens are grouped into areas that are repeatedly-arranged zones in order of closeness to the center. The zones include a central zone and annular zones. Both the central zone and the annular zones each are given a reference numeral “70”. In each of the annular zones 70, one of the low refractive index concentric parts 72 and one of the high refractive index concentric parts 71 are arranged in this order. A number assigned to each of the zones 70 that are arranged outwardly from the center OC is expressed as “k”, and the number “k” is an integer that is equal to or larger than one. The CP2 (central concentric part 71) forms a first one (k=1) of the zones 70 according to the present embodiment.

A radius of the central zone 70 and widths c of the annular zones 70 are each equal to or less than a wavelength of light emitted from the light-emitting layer 13, and has a same value of 200 [nm] in the present embodiment.

In the present embodiment, the low refractive index layer 66 and the low refractive index concentric parts 72 are each formed by the low refractive index transparent material A composed of SiO₂, and the high refractive index layer 68 and the high refractive index concentric parts 71 are each formed by the high refractive index transparent material B composed of TiO₂.

<Refractive Index Distribution>

The following describes a design concept of the refractive index distribution of the diffraction lens 67.

The diffraction lens 67 is formed such that saw-tooth changes of effective refractive indexes of the zones 70 occurs radially from the center. This means that a curve showing the changes of effective refractive indexes of the zones 70 have a shape formed by repeated saw-tooth portions. Here, the saw-tooth portion is composed of a portion that is sharply elevated in a radial direction and a portion that slopes gradually from a top point of the sharply-elevated portion in the radial direction. The lens in which the saw-tooth changes of the effective refractive indexes occurs has a diffraction effect on light.

In the diffraction lens 67, setting is made such that the effective refractive index n_{eff} of each zone 70 is approximately equal to a refractive index n(r) determined by the following equation (9) when the effective refractive index of the central zone 70 is n0, m is an integer incrementally assigned, in order from the center outwardly, starting with 0, to one of the zones based on each saw-tooth change and a wavelength of light emitted from the light-emitting layer 13 is λ. Here, a first one of the areas is an area between the center and a first peak in the saw-tooth change, and a second one of the areas onwards each is an area between two consecutive peaks in the saw-tooth change. Note that a focal distance is f [μm], a thickness of the diffraction lens 67 is L [μm], and a refractive index of a layer that is adjacent to a light incident surface of the diffraction lens 67 is ni.

$$n ( r ) = n 0 - ( \frac{ni}{2 fL} ) {r}^{2} + \frac{m λ}{L} \qquad ( 9 )$$

The number m of each area including the zone 70 can be obtained by the following equation (10) with use of a Floor function that truncates decimal points.

$$m = Floor ( ( \frac{ni}{2 f λ} ) {r}^{2} ) \qquad ( 10 )$$

In order for the effective refractive index n_{eff} of each zone 70 to approximately match the refractive index n(r) determined by the above-stated equations (9) and (10), it is necessary to adjust a ratio between widths a and b (in a radius direction) of the high refractive index concentric part 71 and the low refractive index concentric part 72 respectively that are included in the annular zone 70 as with the gradient index lens 17 described in the above first embodiment. Specifically, the width a of the zone 70 needs to be a value that can be obtained by the following equation (11) when the inner circumference radius of each zone 70 is a distance r.

$$a = \frac{c}{( {n}_{high} - {n}_{low} )} ( n 0 - {n}_{low} - ( \frac{ni}{2 fL} ) {( k - 1 )}^{2} {c}^{2} + \frac{m λ}{L} ) \qquad ( 11 )$$

The width b can be calculated by the width a obtained by the above-stated equation (11) and the width c of the zone 70.

Note that not only the number m assigned to one of the zones based on each of the saw-tooth changes but also a width of each of the zones in a radial direction are determined by the above-stated equation (10).

<Examples of Refractive Index Distribution>

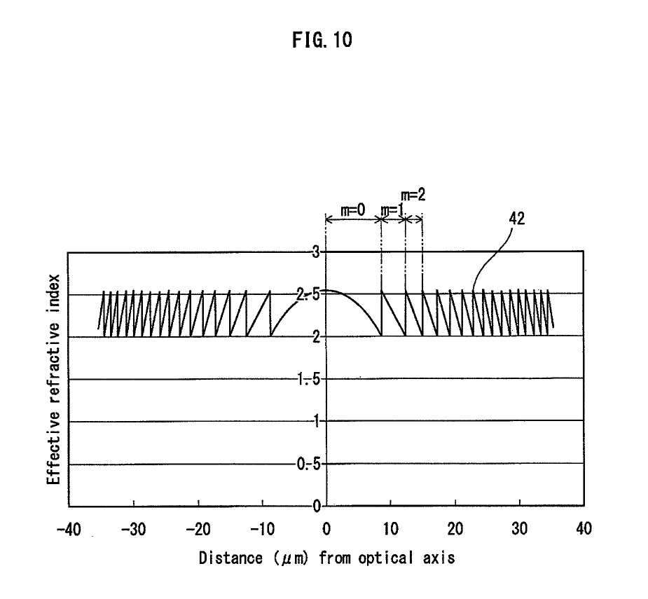

FIG. 10 shows a refractive index distribution of the diffraction lens 67.

In FIG. 10, a vertical axis shows an effective refractive index n_{eff}, and a horizontal axis shows a distance r from the center OC. A refractive index distribution curve 42 shown in FIG. 10 shows effective refractive indexes n_{eff} set based on the above-stated equations (9) and (10). Parameters used in this example are as follows: a focal distance f is 100 [μm], a thickness L of the diffraction lens 67 is 1 [μm], a wavelength λ of light emitted from the light-emitting layer 13 is 572 [nm], an effective refractive index n0 of the central zone 70 in the wavelength λ is 2.53 and a refractive index ni in the wavelength λ is 1.46. The effective refractive index n0 is used as the refractive index of the CP2 (TiO₂=2.53), and the refractive index ni is used as the refractive index of the low refractive index layer 66 (SiO₂=1.46). Note that the diffraction lens 67 has an effective diameter of 70 [μm], and the number of zones 70 included in the diffraction lens 67 is 350.

The shape of the refractive index distribution curve 42 shows saw-tooth changes of the effective refractive indexes n_{eff} that occurs radially from the center. It can be seen from the refractive index distribution curve 42 that a distance between the center OC and the first peak (m=0) is longest, and that each distance between consecutive peaks slightly decreases compared to a distance between other consecutive peaks that are closer to the center OC than the consecutive peaks. Here, the distance between the center OC and the first peak corresponds to the radius of the area between the center OC and the first peak, and each distance between the consecutive peaks corresponds to the width of the area between the consecutive peaks. When each distance between the consecutive peaks slightly decreases compared to a distance between other consecutive peaks that are closer to the center OC than the consecutive peaks, light passing through a position more distant from the OC is more affected by the diffraction effect. As a result, the light diffracts towards the optical axis.

In the above-described light-emitter 60, the divergence angle of light emitted from the light-emitting layer 13 is suppressed by the diffraction lens 67 as with the gradient index lens 17 described in the first embodiment. Thus, it is possible to suppress the total internal reflection components of light incident on each of an interface between the diffraction lens 67 and the high refractive index layer 18, an interface between the high refractive index layer 18 and the sealing layer 23 and an interface between the sealing layer 23 and the glass plate 24. As a result, light takeoff efficiency of the light-emitter 60 can be enhanced.

Also, in the diffraction lens 67, a focal distance can be adjusted by changing distances between the two consecutive peaks in the saw-tooth change of the refractive indexes. Therefore, the focal distance can be shortened compared to the gradient index lens 17. Therefore, the light-emitter can be further downsized.

<High Order Equation of Refractive Index>

In the present embodiment, the following equation (12) which is the above-stated equation (9) to which the third or higher order term is added in order to enhance the accuracy of the calculation of the refractive index n(r).

$$n ( r ) = n 0 - ( ( \frac{ni}{2 fL} ) {r}^{2} + {a}_{n} {r}^{n} ) + \frac{m λ}{L} \qquad ( 12 )$$

In this case, the number m of each area can be obtained by the following equation (13).

$$m = Floor ( ( \frac{ni}{2 fL} ) {r}^{2} + {a}_{n} {r}^{n} ) \qquad ( 13 )$$

<Limitation on Size of Line Width of High Refractive Index Concentric Part>

Note that although the width a of the high refractive index concentric part 71 and the width b of the low refractive index concentric part 72 are not limited in particular, it is preferable to limit the range in order to facilitate the manufacturing of the diffraction lens 67.

Since the effective refractive index n_{eff} of each zone 70 can be set by adjusting the widths a and b of the concentric parts 71 and 72, and the width a of the central zone 70 is largest from among the widths a of the zones 70, the ranges of the widths a and b of the concentric parts 71 and 72 included in each zone 70 can be indirectly limited. That is, it is preferable that the effective refractive index n0 and the thickness L are set so as to satisfy the following equations (14) to (16).

$$\begin{matrix}0.85 {n}_{high} \leq n 0 \leq 0.9 {n}_{high} & ( 14 ) \\ 0.9 \leq L \leq 1.5 & ( 15 ) \\ n 0 \geq \frac{( 0.9 {n}_{high} - 0.85 {n}_{high} )}{( 1.5 - 0.9 )} ( L - 0.9 ) + 0.9 & ( 16 )\end{matrix}$$

The above-stated equation (14) limits the range of the effective refractive index n0, and shows a ratio between the width a of the high refractive index concentric part 71 included in the central zone 70 and a radius of the central zone 70. This shows a minimum value of a ratio of the width b of the low refractive index concentric part 72 included in each zone 70 to the corresponding zone 70. Note that when the range of the effective refractive index n0 is limited by the above-stated equation (14), the central zone 70 includes the low refractive index concentric part 72 unlike the CP2 composed of only the high refractive index concentric part 71.

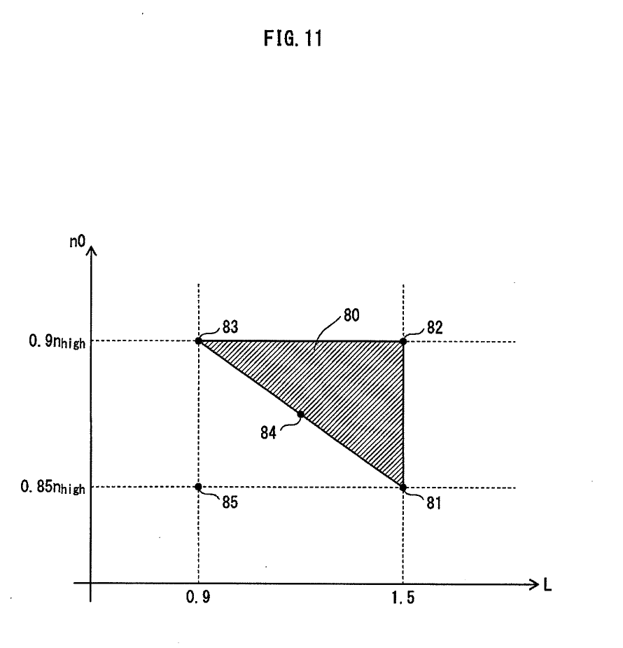

FIG. 11 shows a limited range of the effective refractive index n0 and a thickness L of the diffraction lens 67 that satisfy the above-stated equations (14) to (16). In FIG. 11, a vertical axis shows the effective refractive index n0, and a horizontal axis shows the thickness L of the diffraction lens 67. Also, a range 80 to which the effective refractive index n0 and the thickness L are limited are shown by diagonal lines.

FIG. 11 shows the following cases 81 to 85 each shows a combination of the effective refractive index n0 and the thickness L.

Case 81: n0=0.85 n_{high}; and L=1.5 [μm]

Case 82: n0=0.9 n_{high}; and L=1.5 [μm]

Case 83: n0=0.9 n_{high}; and L=0.9 [μm]

Case 84: n0=0.875 n_{high}; and L=1.2 [μm]

Case 85: n0=0.85 n_{high}; and L=0.9 [μm]

The cases 81 to 84 fall in the limited range 80, and the case 85 does not fall in the limited range 80.

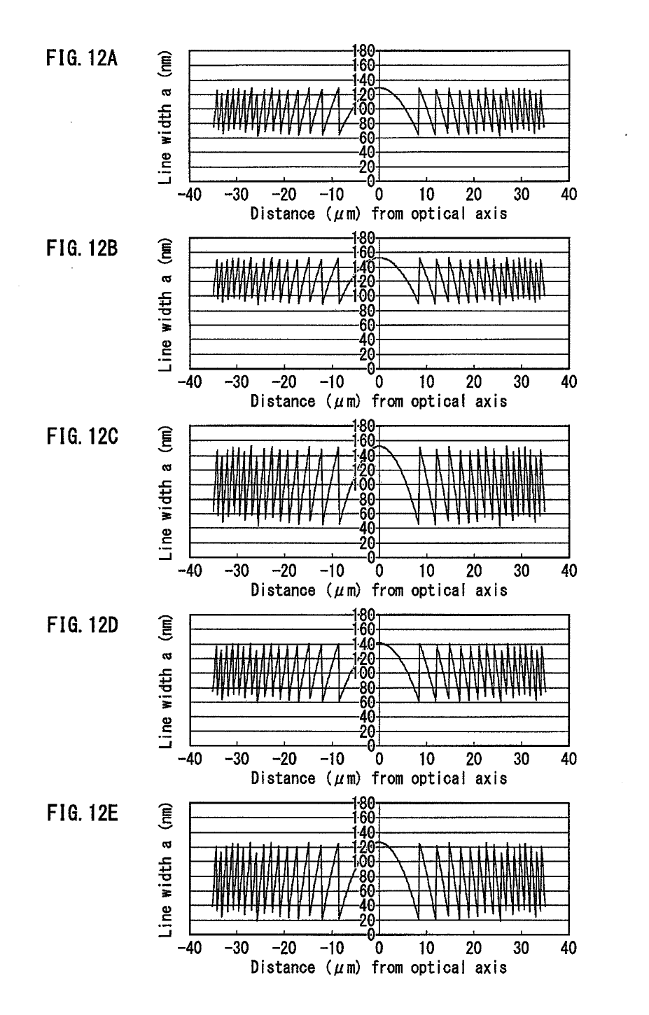

FIG. 12A to FIG. 12E show plots of widths a in the respective zones 70 for realizing the refractive index distributions of the cases 81 to 85 shown in FIG. 11. In each of FIG. 12A to FIG. 12E, a vertical axis shows a width a of the high refractive index concentric part 71, and a horizontal axis shows a distance r from the center OC. Note that each width a is obtained by the above-stated equation (11), and other parameters other than the effective refractive index n0 and the thickness L are set to the same values as the values in the refractive index distribution shown in FIG. 10.

Maximum and minimum values of the widths a shown in FIG. 12A to FIG. 12E are as follows.

Width a in FIG. 12A: Maximum value=129.0 [nm]; and Minimum value=63.2 [nm]

Width a in FIG. 12B: Maximum value=152.7 [nm]; and Minimum value=86.9 [nm]

Width a in FIG. 12C: Maximum value=152.7 [nm]; and Minimum value=43.0 [nm]

Width a in FIG. 12D: Maximum value=140.8 [nm]; and Minimum value=58.6 [nm]

Width a in FIG. 12E: Maximum value=129.0 [nm]; and Minimum value=19.4 [nm]

As shown in the above, the widths a of the high refractive index concentric parts 71 in the cases 81 to 84 as shown in FIG. 12A to FIG. 12D fall in the range of 40 [nm] to 160 [nm]. Therefore, the widths b of the low refractive index concentric parts 72 also fall in the range of 40 [nm] to 160 [nm]. Thus, since the minimum values of the width a and the width b can be set to 40 [nm] or more, it is easy to form the concentric parts 71 and 72. As a result, the manufacturing of the diffraction lens 67 can be facilitated.

On the other hand, the width a of the high refractive index concentric part 71 in the case 85 shown in FIG. 12E falls in the range of 19 [nm] to 130 [nm]. In this range, the high refractive index concentric parts 71 can be formed with use of the photolithographic technique. However, it is necessary to form the high refractive index concentric parts 71 each having the width a as small as less than 30 [nm].

<Manufacturing Method>

The following describes a method of manufacturing the diffraction lens 67.

The diffraction lens 67 having the above-described structure can be manufactured with use of the photolithographic technique as with the gradient index lens 17 manufactured in the manufacturing method pertaining to the above-described first embodiment.

The method of manufacturing the diffraction lens 67 is different from the method of manufacturing the gradient index lens 17 in that a ratio between the width a of the high refractive index concentric part 71 and the width b of the low refractive index concentric part 72 included in each of the zones 70 is set such that saw-tooth changes of the effective refractive indexes n_{eff} occurs in the diffraction lens 67. The rest of manufacturing procedures of the diffraction lens 67 is the same as manufacturing procedures of the gradient index lens 17 shown in FIG. 6 and FIG. 7. Therefore, the description thereof is omitted.

In the method of manufacturing the gradient index lens 17, the width a of the high refractive index concentric part 31 is calculated with use of the above-stated equation (7). However, in the method of manufacturing the diffraction lens 67, the width a of the high refractive index concentric part 71 is calculated with use of the following equation (17).

$$a = \frac{c}{( {n}_{high} - {n}_{low} )} ( n 0 - {n}_{low} - ( \frac{ni}{2 fL} ) {( k - 1 )}^{2} {c}^{2} + \frac{m λ}{L} ) \qquad ( 17 )$$

In the above-stated equation (17), the distance r in the above-stated equation (11) is replaced with inner circumference radius (k−1)c in the k^{th} zone 70.

This concludes the description of the differences between the method of manufacturing the diffraction lens 67 and the method of manufacturing the gradient index lens 17.

According to the above-described method of manufacturing the diffraction lens 67, the photolithographic technique is used as with the method of manufacturing the gradient index lens 17. Therefore, it is possible to evenly and precisely manufacture each of the concentric parts 71 and 72 of the diffraction lens 67 that are up to 30 [nm] in width, using the photolithographic technique. Thus, the same effect as the light-emitter 10 in the above-described first embodiment is obtained with the light-emitter 60.

### Third Embodiment

<Overall Structure of Display Device>

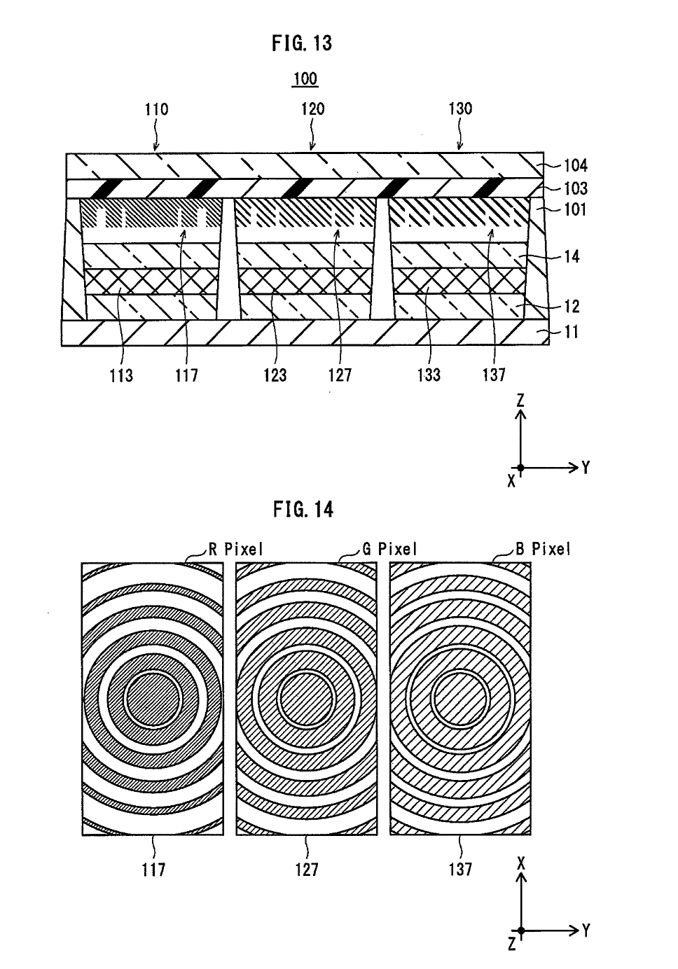

FIG. 13 schematically shows a sectional view of main parts of an organic EL display panel 100 as an example of a display apparatus pertaining to the third embodiment.

The organic EL display 100 includes a light-emitter composing each of RGB pixels. Each of the light-emitters has a feature of including a gradient index lens having an effective refractive index set according to a light wavelength of the pixel composed of the light-emitter. Note that the same elements as the elements of the light-emitter 10 shown in FIG. 1 are given the same references for the purpose of simplification, and the descriptions thereof are omitted.

In the present embodiment, a light-emitter 110 composes a pixel R, a light-emitter 120 composes a pixel G, and a light-emitter 130 composes a pixel B.

Each of the light-emitters 110, 120 and 130 has the same structure as the light-emitter 10 pertaining to the above-described first embodiment, and has a laminating structure in which an electrode, a light-emitting layer, a transparent electrode, a low refractive index layer, a gradient index lens and a high refractive index layer are laminated in this order on a substrate.

Also, the light-emitters 110, 120 and 130 are provided on banks 101, and are arranged in a matrix form (not shown). A sealing layer 103 and a glass layer 104 are formed on each of the light-emitters 110, 120 and 130 and each of the banks 101.

<Detailed Structure>

The light-emitter 110 has a light-emitting layer 113 that emits red light and a gradient index lens 117 having an effective refractive index according to a wavelength of red light. The light-emitter 120 includes a light-emitting layer 123 that emits green light and a gradient index lens 127 having an effective refractive index according to a wavelength of the green light. The light-emitter 130 includes a light-emitting layer 133 that emits blue light and a gradient index lens 137 having an effective refractive index according to a wavelength of the blue light.

FIG. 14 schematically shows plane views of the gradient index lenses 117, 127 and 137 of the respective R, G and B pixels. In FIG. 14, high refractive index concentric parts are areas shown by diagonal lines, and low refractive index concentric parts are solid areas.

Setting is made such that an effective refractive index in each of the gradient index lenses 117, 127 and 137 is approximately equal to a refractive index n(r) obtained by the above-stated equation (1) as with the above-described first embodiment. The refractive index ni in the above-stated equation (1) changes according to a light wavelength. Therefore, how effective refractive indexes are distributed is different among the gradient index lenses 117, 127 and 137. Therefore, a change as to how the high refractive index concentric part closer to the center has a smaller width is different among the gradient index lenses 117, 127 and 137. As show in FIG. 14, the gradient index lens 117 composing the pixel R has the greatest change amount, and the gradient index lens 137 composing the pixel B has the smallest change amount. Note that the changes in widths of the high refractive index concentric parts are exaggerated.

The above-described organic EL display 100 includes the gradient index lens having a refractive index distribution of the effective refractive indexes according to each of the R, G and B pixels so as to suppress the divergence angle of the light emitted from the light-emitting layer, and to suppress the total internal reflection component of light incident on each interface. Thus, it is possible to enhance the light takeoff efficiency for each pixel, and realize energy conservation of the organic EL display 100.

<Manufacturing Method>

The following describes a method of manufacturing the gradient index lenses 117, 127 and 137 having the above-described structure.

The method of manufacturing the above-described gradient index lenses 117, 127 and 137 pertaining to the present embodiment is mainly different from the method of manufacturing the gradient index lens 17 pertaining to the above-described first embodiment in that the manufacturing method pertaining to the present embodiment performs patterning of concentric patterns for manufacturing gradient index lenses for a plurality of pixels, and that prior to determining an area of an concentric part to which each selected position on the upper surface of a resist film belong, judgment of an area including a pixel to which the selected position belong is performed.

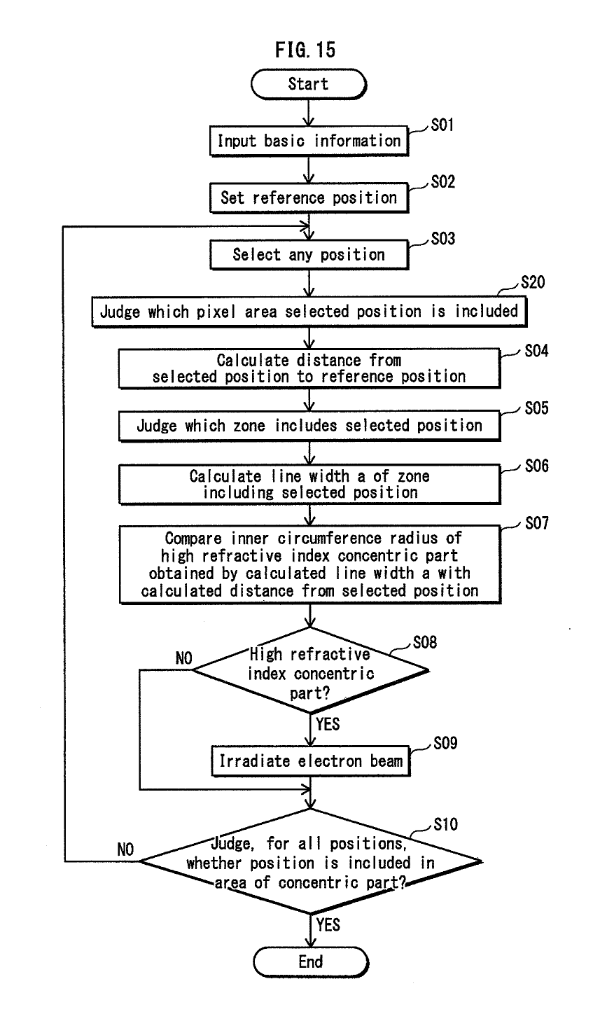

FIG. 15 is a flowchart showing procedures for an area judgment in a patterning process of the present embodiment. In the procedures for the judgment shown in FIG. 15, a significant difference from the manufacturing procedures of the gradient index lens 17 shown in FIG. 7 is that the judgment step shown in FIG. 15 includes, between the Step S03 and Step S04, a Step S20 for determining a pixel area (i, j) to which any selected position (x, y) on the resist film belong.

Also, since the method of manufacturing the above-described gradient index lenses 117, 127 and 137 pertaining to the present embodiment performs patterning of a plurality of concentric patterns on the resist film, the method of manufacturing the above-described gradient index lenses 117, 127 and 137 pertaining to the present embodiment is different from the method of manufacturing the gradient index lens 17. The following describes the differences. Note that a description of the same manufacturing steps as the manufacturing steps of the gradient index lens 17 shown in FIG. 6 and FIG. 7 are omitted for the purpose of simplification.

[1] In inputting the basic information in Step S01, basic information regarding a lens design for each of the R, G and B pixels is inputted. Also, in the present embodiment, a size of a gradient index lens for each pixel is expressed by xL and yL.

[2] In the setting of the basic point in Step S02, a position of an optical axis of each pixel on the upper surface of the resist film is set as a reference position (xᵢ, yᵢ).

Here, i and j indicate i^{th} and j^{th} pixel areas respectively from among the pixel areas arranged in a matrix form.

[3] Step S03 is the same as Step S03 described in the first embodiment.

[4] Here, the pixel area (i, j) to which the selected position (x, y) belongs is obtained by the following equations (18) and (19) before proceeding to Step S04 (S20).

$$\begin{matrix}\vert x - {x}_{i} \vert \leq \frac{xL}{2} & ( 18 ) \\ \vert y - {y}_{j} \vert \leq \frac{yL}{2} & ( 19 )\end{matrix}$$

[5] In Step S04, a distance r from the selected position (x, y) to the reference position (xᵢ, yᵢ) in the pixel area (i, j) is calculated by the following equation (20).

r=\sqrt{(x−xᵢ)²+(y−yⱼ)²} (20)

[6] Step S05 is the same as Step S05 described in the first embodiment.

[7] In calculating the width a of the high refractive index concentric part in Step S06, a refractive index ni according to each of the R, G and B pixels is used in the above-stated equation (7).

[8] Subsequent Steps S07 to S10 are the same as Steps S07 to S10 described in the first embodiment.

According to the above-described method of manufacturing the gradient index lenses 117, 127 and 137, it is possible to evenly and precisely manufacture the concentric parts that are up to 30 [nm] in width that are included in gradient index lenses for the plurality of pixels, using the photolithographic technique as with the method of manufacturing the gradient index lens 17. Thus, the same effect as the light-emitter 10 in the above-described first embodiment is obtained with the light-emitter composing each of the R, G and B pixels included in the organic EL display 100.

Although each of the light-emitters has a gradient index lens in the present embodiment, each of the light-emitters may have a diffraction lens described in the second embodiment. In that case, however, it is necessary to set an effective refractive index of each diffraction lens according to a wavelength of each of the R, G and B pixels. Therefore, the above-stated equation (17) is used as with the above-descried second embodiment for calculating the width a in Step S06.

Also, an application of the manufacturing method pertaining to the third embodiment is not limited to the light-emitter included in the display apparatus such as an organic EL display. Therefore, it is preferable to use the manufacturing method pertaining to the third embodiment in manufacturing a plurality of gradient index lenses (diffraction lenses) in the patterning process.

### Fourth Embodiment

<Overall Structure of Lighting Apparatus>

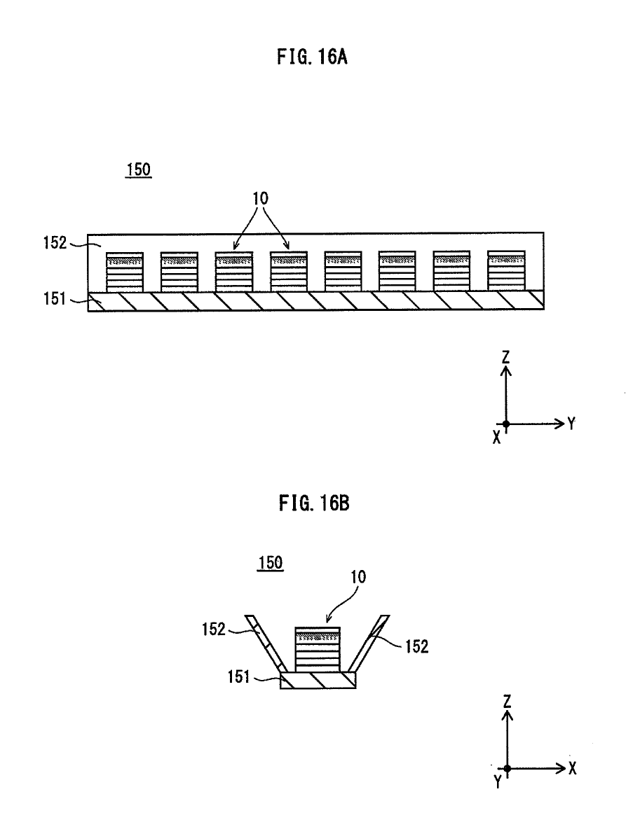

FIG. 16 shows an outline of a lighting apparatus 150 including the light-emitter 10 pertaining to the above-described first embodiment, as an example of the lighting apparatus pertaining to the fourth embodiment of the present invention. FIG. 16A schematically shows a Y-Z sectional view of the lighting apparatus 150, and FIG. 16B schematically shows an X-Z sectional view of the lighting apparatus 150.

The lighting apparatus 150 is composed of a base 151, a reflection member 152 and a plurality of the light-emitters 10 arranged on the base 151. The plurality of light-emitters 10 are electrically connected to a conductive pattern formed on the base 151, and emit light by drive power supplied from the conductive pattern. The distribution of part of light emitted from each of the plurality of the light-emitters 10 is controlled by the reflection member 152.

Since the above-described light-emitter 150 includes the light-emitter 10 in which the divergence angle of emitted light is suppressed by the gradient index lens, the light-emitter 150 has improved light takeoff efficiency. Also, since the gradient index lens in each of the plurality of the light-emitters 10 can be manufactured evenly and precisely. Therefore, a variation in effect of suppressing the divergence angle of the emitted light can be suppressed. As a result, a variation in light takeoff efficiency can be suppressed.

Even when the light-emitter 60 pertaining to the above-described second embodiment is used in the lighting apparatus 150 instead of the light-emitter 10, the same effect as the above-stated effect can be obtained.

<Modifications>

This concludes the description of the light-emitter pertaining to the present invention, the display apparatus and the lighting apparatus each including the light-emitter, and the method of manufacturing the light-emitter based on the embodiments. However, the present invention is not limited to these embodiments. The following modifications may be possible, for example.

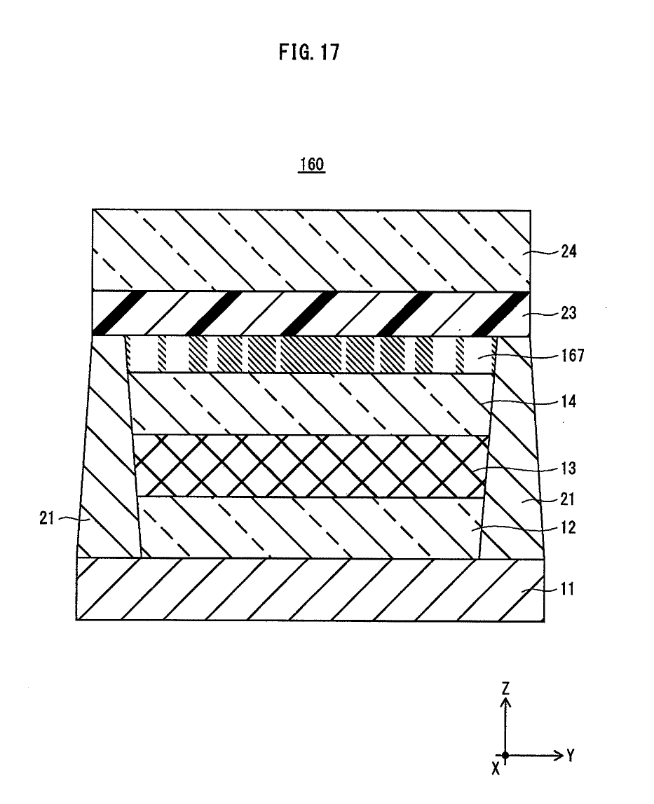

(1) Although the light-emitter includes the lens layer composed of the low refractive index layer, the gradient index lens (diffraction lens) and the high refractive index layer, the light-emitter may include a lens layer composed only of the gradient index lens (diffraction lens). For example, as shown in FIG. 17, the light-emitter 160 may have a structure in which the electrode 12, the light-emitting layer 13, the transparent electrode 14 and the gradient index lens 167 are laminated in the stated order on the substrate 11. In such a case, a refractive index of the transparent electrode 14 is used as the refractive index ni used in each of the above-stated equations.

(2) Although the low refractive index layer, the gradient index lens (diffraction lens) and the high refractive index layer are laminated in the stated order in the above embodiments, the order of the high refractive index layer and the low refractive index layer may be changed. That is, the high refractive index layer, the gradient index lens (diffraction lens) and the high refractive index layer may be laminated in this order on the transparent electrode.

(3) Although the top emission structure that allows light to enter from the opposite side to the substrate is adopted in the above embodiments, a bottom emission structure that allows light to enter from the substrate may be adopted. In that case, the same effect as the top emission structure may be obtained by providing the gradient index lens (diffraction lens) between the transparent substrate and the light-emitting layer with use of the transparent substrate.

(4) Although each of the annular zones is composed of one of the high refractive index concentric parts and one of the low refractive index concentric parts, each of the zones may include a plurality of the high refractive index concentric parts and a plurality of the low refractive index concentric parts. In that case, a sum of the widths a of the high refractive index concentric parts in each zone and a sum of the widths b of the low refractive index concentric parts in each zone may be used as the parameters a and b that are used in some of the above-stated equations.

(5) Although each of the zones is composed of the low refractive index concentric part formed of the low refractive index transparent material A and the high refractive index concentric part formed of the high refractive index transparent material B in the above embodiments, each of the zones may be composed of concentric parts formed of three or more kinds of transparent materials each having a different refractive index. The number of concentric parts that form each zone and types of transparent materials may be arbitrarily changed as long as a radius of the central zone and widths of the annular zones is equal to or less than the wavelength of the light emitted from the light-emitting layer.

Also, the number of concentric parts, types of transparent materials and the radius or the widths may be arbitrarily changed for each zone. For example, the gradient index lens or the diffraction lens may be composed of zones each including only one concentric part.

(6) Although SiO₂ is used as the low refractive index transparent material A, and TiO₂ is used as the high refractive index transparent material B in the above-described embodiments, one of TiO₂, ZrO₂, Nb₂O₅, Si₃N₄, Si₂N₃ and SiO₂ may be used as each of the low refractive index transparent material A and the high refractive index transparent material B. Furthermore, each concentric part to be formed of the low refractive index transparent material A may be space. In such a case, it is preferable that the high refractive index layer is disposed on the transparent electrode side in the lens layer.

(7) Although the electron beam is directly irradiated on the resist film in the patterning process in the manufacturing methods of the above-described embodiments, a concentric pattern may be formed on the photo mask by the electron-beam lithography, and the concentric pattern may be transferred on the resist film by exposed light with use of the photo mask.

(8) Although the effective refractive index n_{eff} of each zone is calculated with the inner circumference radius of the zone being the distance r, the calculation may be performed with an outer radius of the zone being the distance r. Also, the distance r may be a distance from an intermediate position between the inner circumference and the outer circumference of the zone.

Although the present invention has been fully described by way of examples with reference to the accompanying drawings, it is to be noted that various changes and modifications will be apparent to those skilled in the art. Therefore, unless such changes and modifications depart from the scope of the present invention, they should be construed as being included therein.

1. A light-emitter, comprising:
a first electrode layer;
a second electrode layer;
a light-emitting layer positioned between the first electrode layer and the second electrode layer;
and
a gradient index lens positioned proximate the second electrode layer opposite the light-emitting layer and including a plurality of concentric parts, wherein
the plurality of concentric parts are grouped into a central zone and annular zones, each of the annular zones including at least two of the plurality of concentric parts,
one of the at least two of the plurality of concentric parts included in each of the annular zones has a refractive index different from a refractive index of another one of the at least two of the plurality of concentric parts,
a wavelength of light emitted from the light-emitting layer is equal to or greater than a radius of the central zone and a width of each of the annular zones, and
an effective refractive index of each of the annular zones decreases in an outward direction from a center of the gradient index lens.

2. The light-emitter of claim 1, wherein
the effective refractive index of each of the annular zones is approximately equal to a refractive index n(r), wherein
$$n ( r ) = n 0 - ( \frac{ni}{2 fL} ) {r}^{2} ,$$
where r is a distance from the center to an inner circumference radius of a corresponding one of the annular zones,
n0 is an effective refractive index of the central zone,
f is a focal distance of the gradient index lens,
L is a thickness of the gradient index lens, and
ni is a refractive index of a layer that is adjacent to a light incident surface of the gradient index lens.

3. The light-emitter of claim 1, wherein
a number of the at least two of the plurality of concentric parts included in each of the annular zones is two.

4. The light-emitter of claim 1, wherein
a transparent layer is positioned between the gradient index lens and the second electrode layer.

5. The light-emitter of claim 4, wherein
a refractive index of the transparent layer is equal to a lowest one of refractive indexes of the plurality of concentric parts.

6. The light-emitter of claim 1, wherein
the radius of the central zone is approximately equal to the width of each of the annular zones.

7. The light-emitter of claim 1, wherein
the width of each of the plurality of concentric parts is at least 40 nm.

8. The light-emitter of claim 1, wherein
the one of the at least two of the plurality of concentric parts comprises a transparent material that is one of titanium oxide, zirconium oxide, niobium oxide, silicon nitride, silicon oxide, and space, and
the another one of the at least two of the plurality of concentric parts comprises another one of the transparent material.

9. A display apparatus having a plurality of pixels each including the light-emitter of claim 1.

10. The display apparatus of claim 9, wherein
a width ratio of the at least two of the plurality of concentric parts included in each of the annular zones is set according to a type of light emitted from the light-emitting layer, the type of light being at least one of a red light, a green light and a blue light.

11. A lighting apparatus having the light-emitter of claim 1.

12. A light-emitter, comprising:
a first electrode layer;
a second electrode layer;
a light-emitting layer positioned between the first electrode layer and the second electrode layer;
and
a diffraction lens positioned proximate the second electrode layer opposite the light-emitting layer and including a plurality of concentric parts, wherein
the plurality of concentric parts are grouped into a central zone and annular zones, each of the annular zones including at least two of the plurality of concentric parts, and
one of the at least two of the plurality of concentric parts included in each of the annular zones has a refractive index different from a refractive index of another one of the at least two of the plurality of concentric parts,
a wavelength of light emitted from the light-emitting layer is equal to or greater than a radius of the central zone and a width of each of the annular zones, and
a width ratio of the at least two of the plurality of concentric parts included in each of the annular zones is set such that saw-tooth changes of effective refractive indices of the annular zones occur spatially from a center.

13. The light-emitter of claim 12, wherein
the effective refractive index of each of the annular zones is approximately equal to a refractive index n(r), wherein
$$n ( r ) = n 0 - ( \frac{ni}{2 fL} ) {r}^{2} + \frac{m λ}{L} ,$$
where r is a distance from the center to an inner circumference radius of a corresponding one of the annular zones,
n0 is an effective refractive index of the central zone,
f is a focal distance of the diffraction lens,
L is a thickness of the diffraction lens,
m is an integer incrementally assigned, in order from the center outwardly, starting with 0, to the central zone and the annular zones based on each saw-tooth change,
λ is the wavelength of the light emitted from the light-emitting layer, and
ni is a refractive index of a layer that is adjacent to a light-emitting surface of the diffraction lens.

14. The light-emitter of claim 13, wherein
m is obtained via a Floor function, and
$$m = Floor ( ( \frac{ni}{2 f λ} ) {r}^{2} ) .$$

15. The light-emitter of claim 12, wherein
a number of the at least two of the plurality of concentric parts included in each of the annular zones is two.

16. The light-emitter of claim 15, wherein
the central zone includes at least two of the plurality of concentric parts,
when the one of the at least two of the plurality of concentric parts included in each of the annular zones has a higher refractive index n_{high} that is greater than the refractive index of the another of the at least two of the plurality of concentric parts, a thickness L of the diffraction lens and a width ratio of the at least two of the plurality of concentric parts included in the central zone are set such that an effective refractive index n0 of the central zone satisfies:
0.85n_{high}≦n0≦0.9n_{high},
the thickness L satisfies:
0.9≦L≦1.5, and
a relationship between the effective refractive index n0 and the thickness L satisfies:
$$n 0 \geq \frac{( 0.9 {n}_{high} - 0.85 {n}_{high} )}{( 1.5 - 0.9 )} ( L - 0.9 ) + 0.9 .$$

17. The light-emitter of claim 12, wherein
the effective refractive index of each of the annular zones is approximately equal to a refractive index n(r), and
$$n ( r ) = n 0 - ( ( \frac{ni}{2 fL} ) {r}^{2} + {a}_{n} {r}^{n} ) + \frac{m λ}{L} ,$$
where r is a distance from the center to an inner circumference radius of a corresponding one of the annular zones,
n0 is an effective refractive index of the central zone,
f is a focal distance of the diffraction lens,
L is a thickness of the diffraction lens,
m is an integer incrementally assigned, in order from the center outwardly, starting with 0, to the central zone and the annular zones based on each saw-tooth change,
λ is the wavelength of the light emitted from the light-emitting layer,
ni is a refractive index of a layer that is adjacent to a light incident surface of the diffraction lens,
n is an integer greater than two, and
aₙ is an n^{th} coefficient.

18. The light-emitter of claim 17, wherein
m is obtained via a Floor function, and
$$m = Floor ( ( \frac{ni}{2 fL} ) {r}^{2} + {a}_{n} {r}^{n} ) .$$

19. The light-emitter of claim 12, further comprising:
a transparent layer positioned between the diffraction lens and the second electrode layer.

20. The light-emitter of claim 19, wherein
a refractive index of the transparent layer is equal to a lowest one of refractive indexes of the plurality of concentric parts.

21. The light-emitter of claim 12, wherein
the radius of the central zone is approximately equal to the width of each of the annular zones.

22. The light-emitting device of claim 12, wherein
the width of each of the plurality of concentric parts is at least 40 nm.

23. The light-emitter of claim 12, wherein
the one of the at least two of the plurality of concentric parts comprises a transparent materials that is one of titanium oxide, zirconium oxide, niobium oxide, silicon nitride, silicon oxide, and space, and
the another one of the at least two of the plurality of concentric parts comprises another one of the transparent material.

24. A display apparatus having a plurality of pixels each including the light-emitter of claim 12.

25. The display apparatus of claim 24, wherein
the width ratio of the at least two of the plurality of concentric parts included in each of the annular zones is set according to a type of light emitted from the light-emitting layer, the type of the light being at least one of a red light, a green light and a blue light.

26. A lighting apparatus having the light-emitter of claim 12.

27. A method of manufacturing a light-emitter, comprising:
a first process of forming a resist pattern for forming a gradient index lens including a plurality of concentric parts, each of the plurality of concentric parts having one of a lower refractive index and a higher refractive index, the concentric parts having the lower refractive index and the concentric parts having the higher refractive index being arranged alternately from a center, the plurality of concentric parts being grouped into a central zone and annular zones, the central zone having a radius that is approximately equal to a width of each of the annular zones and including one of one and two of the plurality of concentric parts, each of the annular zones including one of the plurality of concentric parts having the lower refractive index and one of the plurality of concentric parts having the higher refractive index; and
a second process of forming the gradient index lens with the resist pattern, the gradient index lens formed proximate a second electrode layer and opposite a light-emitting layer, the light emitting layer positioned between a first electrode and the second electrode, wherein
the first process includes:
forming a resist film;
selecting a selected position (x, y) located on a surface of the resist film;
calculating a distance r between the selected position (x, y) and a reference position (x₀, y₀) that corresponds to the center;
calculating a number k of one of the central zone and one of the annular zones that includes the selected position (x, y) based on the calculated distance r and the width c of each of the annular zones;
calculating a width a of one of the concentric parts having the higher refractive index, wherein
$$a = \frac{c}{( {n}_{high} - {n}_{low} )} ( n 0 - {n}_{low} - ( \frac{ni}{2 fL} ) {( k - 1 )}^{2} {c}^{2} )$$
c is a width of each of the annular zones,
n_{low} is the lower refractive index,
n_{high} is the higher refractive index,
ni is a refractive index of a layer that is adjacent to a light incident surface of the gradient index lens,
f is a focal distance of the gradient index lens,
L is a thickness of the gradient index lens, and
n0 is an effective refractive index of the central zone; and
judging whether to remove a portion of the resist film including the selected position (x, y) depending on whether the calculated distance r satisfies:
r≦kc−a.

28. A method of manufacturing a light-emitter, comprising:
a first process of forming a resist pattern for forming a diffraction lens including a plurality of concentric parts, each of the plurality of concentric parts having one of a lower refractive index and a higher refractive index, the concentric parts having the lower refractive index and the concentric parts having the higher refractive index being arranged alternately from a center, the plurality of concentric parts being grouped into a central zone and annular zones, the central zone having a radius that is approximately equal to a width of each of the annular zones and including one of one and two of the plurality of concentric parts, each of the annular zones including one of the plurality of concentric parts having the lower refractive index and one of the plurality of concentric parts having the higher refractive index, a width ratio of the plurality of concentric parts included in each of the annular zones being set such that saw-tooth changes of effective refractive indices of the annular zones occur spatially from the center; and
a second process of forming the diffraction lens with the resist pattern the diffraction lens formed proximate a second electrode layer and opposite a light-emitting layer, the light emitting layer positioned between a first electrode and the second electrode, wherein
the first process includes:
forming a resist film;
selecting a selected position (x, y) located on a surface of the resist film;
calculating a distance r between the selected position (x, y) and a reference position (x₀, y₀) that corresponds to the center;
calculating a number k of one of the central zone and one of the annular zones that includes the selected position (x, y) based on the calculated distance r and the width c of each of the annular zones;
calculating a width a of one of the concentric parts having the higher refractive index, wherein
$$a = \frac{c}{( {n}_{high} - {n}_{low} )} ( n 0 - {n}_{low} - ( \frac{ni}{2 fL} ) {( k - 1 )}^{2} {c}^{2} + \frac{m λ}{L} )$$
c is a width of each of the annular zones,
n_{low} is the lower refractive index,
n_{high} is the higher refractive index,
ni is a refractive index of a layer that is adjacent to a light incident surface of the diffraction lens,
f is a focal distance of the diffraction lens,
L is a thickness of the diffraction lens,
n0 is an effective refractive index of the central zone,
λ is a wavelength of light emitted from the light-emitting layer, and
m is an integer incrementally assigned, in order from the center outwardly, starting with 0, to the central zone and the annular zones based on each saw-tooth change; and
judging whether to remove a portion of the resist film including the selected position (x, y) depending on whether the calculated distance r satisfies:
r≦kc−a.
